(19) United States
(12) Patent Application Publication
(10) Pub. No.: US 2024/0037442 A1
(43) Pub. Date: Feb. 1, 2024

(54) GENERATING INDICATIONS OF LEARNING OF MODELS FOR SEMICONDUCTOR PROCESSING

(71) Applicant: Applied Materials, Inc., Santa Clara, CA (US)

(72) Inventor: Dermot Patrick Cantwell, Sunnyvale, CA (US)

(21) Appl. No.: 17/874,105

(22) Filed: Jul. 26, 2022

(51) Int. Cl. G06N 20/00; G06F 3/0481; H01L 21/66

(52) U.S. Cl. CPC G06N 20/00; G06F 3/0481; H01L 22/12; H01L 22/14

(57) ABSTRACT

A method includes receiving a first value associated with a first input parameter of a model. The method further includes receiving a first plurality of values associated with a second input parameter of the model. The method further includes providing to the model the first value and the first plurality of values. The method further includes receiving a first plurality of outputs from the model. The method further includes preparing the first plurality of outputs for presentation via a presentation element of a graphical user interface. The presentation element includes two axes. The first axis is associated with a first property of a first feature associated with the output from the model. The second axis is associated with a second property of the first feature.

### TECHNICAL FIELD

The instant specification relates to trained models. Specifically, the instant specification relates to generating indications that present model learnings for models associated with semiconductor processing.

### BACKGROUND

Chambers are used in many types of processing systems. Examples of chambers include etch chambers, deposition chambers, anneal chambers, and the like. Typically, a substrate, such as a semiconductor wafer, is placed on a substrate support within the chamber and conditions in the chamber are set and maintained to process the substrate. Often, models are utilized to improve processing procedures. Models may include trained machine learning models and physics-based models.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a non-transitory machine-readable storage medium stores instructions which, when executed, cause a processing device to perform operations. The operations include receiving a first value associated with a first input parameter of a model. The first input parameter is associated with a first processing condition of a semiconductor wafer processing procedure. The operations further include receiving a first plurality of values. The first plurality of values ranges from a lowest value of the first plurality of values to a highest value of the first plurality of values. Each of the first plurality of values is associated with a second input parameter of the model. The second input parameter is associated with a second processing condition of the semiconductor wafer processing procedure. The operations further include providing to the model the first value and the first plurality of values. The operations further include receiving a first plurality of outputs from the model. Each of the first plurality of outputs is associated with the first value and one value of the first plurality of values. Each of the first plurality of outputs is associated with a first feature of one of a first plurality of simulated substrates. The operations further include preparing the first plurality of outputs for presentation via a presentation element of a graphical user interface (GUI). The presentation element includes two axes. A first axis of the two axes corresponds to a first property of the first feature. A second axis of the two axes corresponds to a second property of the first feature. Preparing the first plurality of outputs for presentation includes facilitating generation of a graphic for display in the presentation element that indicates a value of the first property of the first feature and a value of the second property of the first feature associated with each of the first plurality of outputs.

In another aspect of the disclosure, a non-transitory machine-readable storage medium stores instructions which, when executed, cause a processing device to perform operations. The operations receiving a first plurality of outputs from a first model. Each of the first plurality of outputs is associated with a first input value and one value of a first plurality of input values. Each of the first plurality of outputs is associated with a first feature of one of a first plurality of simulated substrates. The operations further include receiving a second plurality of outputs from a second model. Each of the second plurality of outputs is associated with the first value and one value of the first plurality of values. Each of the second plurality of outputs is associated with a second feature of one of the first plurality of simulated substrates. The operations further include preparing the first and second pluralities of outputs for presentation via a presentation element of a GUI. The presentation element includes two axes. A first axis corresponds to a first property of the first feature. A second axis corresponds to a second property of the second feature. Preparing the first and second pluralities of outputs for presentation includes facilitating generation of a graphic for display in the presentation element that indicates, for each simulated substrate of the first plurality of simulated substrates, a value of the first property of the first feature and a value of the second property of the second feature.

In another aspect of the disclosure, a method includes receiving a first value associated with a first input parameter of a first model. The first input parameter is associated with a process recipe for processing a substrate. The method further includes receiving, by the one or more processors, a first plurality of values. The first plurality of values range from a lowest value to a highest value. Each of the first plurality of values is associated with a second input parameter of the first model. The second input parameter is associated with the process recipe. The method further includes providing to the first model the first value and the first plurality of values. The method further includes receiving a first plurality of outputs from the first model. each of the first plurality of outputs is associated with the first value and one of the first plurality of values. Each of the first plurality of outputs is associated with a first feature of a simulated substrate. The method further includes preparing the first plurality of outputs for presentation via a presentation element of a GUI. The presentation element comprises two independent axes. A first axis of the two independent axes corresponding to a first property of the first feature. Preparing the first plurality of outputs for presentation includes facilitating generation of a graphic in the presentation element that visually displays a relationship of the outputs of the first plurality of outputs to the first property of the first feature.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system (exemplary system architecture), according to some embodiments.

FIG. 2 is a block diagram of an example data set generator used to create data sets for a model, according to some embodiments.

FIG. 3 is a block diagram illustrating system for generating output data for analysis of learning of a model, according to some embodiments

FIG. 4A is a flow diagram of a method for generating a data set for a machine learning model, according to some embodiments.

FIG. 4B is a flow diagram of a method for generating a visual representation of learning of a model, according to some embodiments.

FIG. 4C is a flow diagram of a method for generating a visual representation of learning of multiple models, according to some embodiments.

FIG. 4D is a flow diagram of a method for generating a graphic demonstrating learning of a model, according to some embodiments.

FIG. 5A is an example presentation element displaying indications of model learning of one or more models, according to some embodiments.

FIG. 5B is an example presentation element depicting learning of one or more models, according to some embodiments.

FIG. 5C is an example GUI, according to some embodiments.

FIG. 5D is an example presentation element depicting model learning associated with a number of varied input parameters, according to some embodiments.

FIG. 6 is a block diagram illustrating a computer system, according to some embodiments.

### DETAILED DESCRIPTION

Described herein are technologies, methods, systems, and devices related to systematically tracking and/or reporting on learning performed by machine learning models and/or on other types of models such as statistical models. In example, machine learning models associated with manufacturing and/or processing of substrates are discussed in some embodiments. Visual indications of model learning are presented in some embodiments. In some embodiments, visual indications are provided for high dimensional input and outputs spaces, such as those used for machine learning models and for statistical models. Embodiments provide a graphical user interface (GUI) that enables users to easily visualize high dimensional input and outputs spaces, and the relationships therebetween. The GUI enables users to see, for any input conditions, a curve that shows how the input tracks through an output space. Accordingly, the GUI enables users to see how changing an input affects the output of the machine learning model or statistical model. For example, in embodiments that GUI can provide insights as to what a machine learning model has learned and give information on a process being modeled.

Manufacturing equipment is used to produce substrates, such as semiconductor wafers. The properties of these substrates are determined by the conditions in which the substrates were processed. Accurate knowledge of property values in the manufacturing chamber during operation, especially in the immediate vicinity of the substrate, can be used to predict the properties of finished products, consistently produce substrates with the same properties, and tailor processing parameters to optimize substrate production.

Machine learning models and statistical models may be utilized to understand and/or predict substrate processing procedures. For example, a machine learning model and/or statistical model may be trained to receive as input values indicative of processing conditions of a substrate. In some cases, process parameters may be provided to the model as input (e.g., processing recipe set points, such as heater power, plasma generation power, duration of processing, etc.). In some cases, processing conditions may be provided to the model as input (e.g., sensor data collected during substrate processing, such as temperature, pressure, component actuation, etc.). In some cases, a combination of data types may be provided to the model as input. The model may be configured to generate an indication of output of the processing procedure (e.g., one or more predicted measurements of a substrate resulting from processing conditions indicated by the inputs to the model).

In some cases, generating an understanding of model learning may be inconvenient. For example, in some cases a user may consider utilizing a trained machine learning model to develop an understanding (e.g., an intuitive understanding) of how an output (e.g., metrology of a produced substrate) is related to one or more inputs. In conventional systems, a user may provide a set of input conditions to a model (e.g., a machine learning model) and receive from the model one or more predictions of an output substrate. A user may then provide to the model a different set of input conditions and receive from the model one or more predictions of an output substrate associated with the new input conditions. It may be cumbersome, time consuming, etc., to generate an understanding of model learning, to compactly display correlations between inputs and outputs, or the like, using conventional systems. For example, it may be difficult to discern the effect of one input on multiple possible outputs (e.g., multiple predicted measurements of a simulated substrate, multiple predicted properties of the simulated substrate, simulated metrology measurements, etc.). It may be difficult to discern the effect of changing multiple inputs (e.g., changing multiple processing recipe parameters) on one or more outputs. It may be difficult to ascertain the strength of the correlation between an input and an output. It may be difficult to ascertain any non-linearities of the correlation between an input and an output. It may be difficult to ascertain the extent of the available input space or output space of the model, and the relationship of a particular input and/or output to the extent of the space.

In some conventional systems, the effect of an input on an output may be displayed, e.g., via a bar graph. A number of inputs may be placed on one axis (e.g., the x-axis) of a bar graph, with an output on an orthogonal axis (e.g., the y-axis). Variation of one input at a time from some “central” or “baseline” set of inputs may be represented by bars of the graph (e.g., the slope of the output space in the direction of input space associated with the one input may be represented by the size of the bar). In such systems, variations in output response to changes in input over the span of the input space may not be represented (e.g., an output may respond differently to the same change in input from different sets of baseline input conditions). Additionally, effects on a second feature of interest (e.g., a second output) that may be correlated with the first output are not captured in such a representation. In some cases, it may be difficult to ascertain the extent of the input and/or output space of the model from such a representation. It may be difficult to ascertain the relationship between an output associated with a set of inputs and the extent of the output space.

Technologies, methods, and systems of this disclosure may address one or more of these shortcomings of conventional systems. In some embodiments, one or more models (e.g., machine learning models, physics-based models, statistical models, etc.) may receive a set of inputs indicative of processing parameters of a substrate. The model(s) may generate as output one or more indications of predicted features of a substrate (e.g., a semiconductor wafer) associated with the set of inputs. Features may include any on-substrate measurable quantity, e.g., thickness, resistivity, refractive index, extinction coefficient, sheet resistance, geometrical measurements (critical dimension, line width, etch depth, sidewall height, etc.), reflectance, surface characteristics, or the like. In some embodiments, a model may be configured to generate data indicative of a feature of a substrate, e.g., a model may generate as output an indication of one or more predicted thickness measurements of a substrate. In some embodiments, a property of a feature may be of interest. For example, a model may predict thickness of a substrate in several spatial locations of the substrate. A statistical property of the predicted feature, such as average, median, standard deviation, uniformity, etc., of the thickness, may be calculated.

In some embodiments, a graphical user interface (GUI) may be utilized for updating settings of a tool (e.g., a software tool) to be utilized in presenting model learning and/or relationship between inputs and outputs of a model. The GUI may further display results of model learning and/or the relationship between inputs and outputs of a model. The GUI may include a presentation element for displaying one or more plots presenting information related to model learning and/or the relationship between inputs and outputs of a model. The GUI may receive one or more instructions (e.g., via user input). The GUI may receive, for example, user indication of a feature and/or property of a feature of interest (e.g., a user may select one or more outputs of one or more models to be plotted via the presentation element), one or more configuration settings (e.g., to customize the look of a plot depicting model learning, to customize data ranges calculated or shown, etc.), or the like. In some embodiments, various data may be displayed on the same plot via the presentation element, e.g., outputs associated with multiple sets of input conditions may be displayed on the same plot.

In some embodiments, output of one or more machine learning models and/or other models (e.g., statistical models) may be presented on a plot, e.g., a scatter plot. In some embodiments, output from a model may be represented on two axes, e.g., one axis may be associated with one property (e.g., a statistical property) of an output feature and the second axis may be associated with a second property of the output feature. In some embodiments, one axis may be associated with a property of a first output feature and the second axis may be associated with a property of a second output feature (e.g., output from a second model).

In some embodiments, the extent of the output space of the one or more models may be represented. For example, many combinations of inputs (e.g., spanning the input space on which the one or more models were trained or configured) may be provided to the one or more models. Each of the outputs associated with a combination of inputs may be presented on the same plot as one or more outputs associated with specific sets of inputs of interest. In some embodiments, data points representing the extent of the model output space may be presented differently than specific model output (e.g., may be presented in the background of model outputs associated with inputs specified by a user, inputs associated with process optimization, inputs associated with a substrate processing recipe to be optimized, or the like).

In some embodiments, a central or baseline set of inputs may be provided to the one or more models. Output associated with the baseline set of inputs may be presented on the same plot as outputs associated with the extent of the output space. Outputs associated with the extent of the output space may provide a visual indication of limits on the extent of output of the one or more models (e.g., the training output space of the one or more models), as compared to specific outputs (e.g., associated with specific sets of inputs, associated with model learning, etc.) of interest.

In some embodiments, one or more sets of inputs of interest may further be provided to the one or more models, and associated outputs displayed on the plot. For example, multiple values of one input parameter may be provided to the one or more models, while maintaining the other input parameters at the baseline values. For example, all inputs except one may be frozen at an initial value (e.g., the baseline value). A series of values associated with the one input that is not frozen may be generated. For example, the series of values may range from a minimum input value to a maximum input value (e.g., from the minimum value of the input that is within the trained input space of the one or more models to the maximum value of the input that is within the trained input space of the one or more models). In some embodiments, the range of outputs may be displayed via the presentation element of the GUI. In some embodiments, a visual indicator may be displayed to distinguish the output value associated with the minimum value of the varied input from the output associated with the maximum value of the varied input. The series of outputs may generate a curve indicative of model learning or configuration—the shape, length, and density of data points along the curve may be indicative of the effect in output space of varying the input from the minimum input value to the maximum input value.

In some embodiments, multiple inputs may be varied. For example, for a first input, a range of values may be generated. A series of outputs may be received from the one or more models, each associated with a different value of the first input, and a baseline value of all other inputs. Then, a second input may be varied. For the second input, a range of values may be generated. A series of outputs may be received from the one or more models, each output associated with a different value of the second input, and a baseline value of all other inputs (e.g., including the first input). Then, all outputs (e.g., outputs associated with described the extent of the output space of the one or more models, outputs associated with varying the first input, outputs associated with varying the second output, etc.) may be displayed via the presentation element. In some embodiments, the presentation of outputs associated with varying the first input may be visually distinguished from the presentation of outputs associated with varying the second input, e.g., via color, shape, pattern, or the like. In some embodiments, the presentation element may display results of varying several input parameters. A plot may be generated that includes several curves (e.g., collections of points associated with various values ranging from a minimum to a maximum value of an input parameter), each meeting/crossing at an output associated with the baseline input conditions.

In some embodiments, a system may receive (e.g., via the GUI) a user indication of the baseline conditions. In some embodiments, the system may receive (e.g., via the GUI) a user indication of a range of one or more inputs to be varied (e.g., minimum and maximum values). In some embodiments, the system may receive (e.g., via the GUI) an indication of spacing of varied inputs (e.g., how many values of an input to be varied to provide to the one or more models, the spacing between input values, etc.). In some embodiments, the system may provide one or more sets of inputs to the one or more models responsive to user selection (e.g., via the GUI) of one or more settings.

Aspects of the present disclosure provide technical advantages compared to conventional methods. In some embodiments, the effect on one or more output metrics (e.g., as presented by the placement of a set of data points relative to multiple axes) may be displayed as an input parameter is varied through a range of values. Non-linearities (e.g., differences in the change in output value for a given change in input value dependent upon an initial input value) may be visually captured. Ranges of values associated with multiple input parameters may be displayed simultaneously or together. The display (e.g., a plot displayed via a presentation element of a GUI) may include a visual record of learning associated with training the one or more machine learning models (or, in some embodiments, physics-based models, etc.), e.g., a visual record of the effect that varying one or more input values has on output values, as understood by the one or more models. In some embodiments, a user may easily alter settings/parameters of the presentation element, the plot, or the like. For example, a user selection of one or more features (e.g., one or more predicted properties of simulated wafers, simulated metrology measurements, etc.), a user selection of one or more properties of the features (e.g., statistical metrics, geometric constraints, etc.), a user selection of a baseline set of input values, or the like may be easily adjusted. A plot may be quickly updated to display a record of model learning associated with the updated user selections. In this way a user may navigate the output space of a model, may develop an intuitive understanding of model learning, may develop an intuitive understanding of processing input to output property mappings, may make adjustments to process parameters or processing recipes for a target property, or the like.

In one aspect of the disclosure, a non-transitory machine-readable storage medium stores instructions which, when executed, cause a processing device to perform operations. The operations include receiving a first value associated with a first input parameter of a model. The first input parameter is associated with a first processing conditions of a substrate processing procedure. The operations further include receiving a first plurality of values. The first plurality of values ranges from a lowest value of the first plurality of values to a highest value of the first plurality of values. Each of the first plurality of values is associated with a second input parameter of the model. The second input parameter is associated with a second processing condition of the substrate processing procedure. The operations further include providing to the model the first value and the first plurality of values. The operations further include receiving a first plurality of outputs from the model. Each of the first plurality of outputs is associated with the first value and one value of the first plurality of values. Each of the first plurality of outputs is associated with a first feature of one of a first plurality of simulated substrates. The operations further include preparing the first plurality of outputs for presentation via a presentation element of a graphical user interface (GUI). The presentation element includes two axes. A first axis of the two axes corresponds to a first property of the first feature. A second axis of the two axes corresponds to a second property of the first feature. Preparing the first plurality of outputs for presentation includes facilitating generation of a graphic for display in the presentation element that indicates a value of the first property of the first feature and a value of the second property of the first feature associated with each of the first plurality of outputs.

In another aspect of the disclosure, a non-transitory machine-readable storage medium stores instructions which, when executed, cause a processing device to perform operations. The operations receiving a first plurality of outputs from a first model. Each of the first plurality of outputs is associated with a first input value and one value of a first plurality of input values. Each of the first plurality of outputs is associated with a first feature of one of a first plurality of simulated substrates. The operations further include receiving a second plurality of outputs from a second model. Each of the second plurality of outputs is associated with the first value and one value of the first plurality of values. Each of the second plurality of outputs is associated with a second feature of one of the first plurality of simulated substrates. The operations further include preparing the first and second pluralities of outputs for presentation via a presentation element of a GUI. The presentation element includes two axes. A first axis corresponds to a first property of the first feature. A second axis corresponds to a second property of the second feature. Preparing the first and second pluralities of outputs for presentation includes facilitating generation of a graphic for display in the presentation element that indicates, for each simulated substrate of the first plurality of simulated substrates, a value of the first property of the first feature and a value of the second property of the second feature.

In another aspect of the disclosure, a method includes receiving a first value associated with a first input parameter of a first model. The first input parameter is associated with a process recipe for processing a substrate. The method further includes receiving, by the one or more processors, a first plurality of values. The first plurality of values range from a lowest value to a highest value. Each of the first plurality of values is associated with a second input parameter of the first model. The second input parameter is associated with the process recipe. The method further includes providing to the first model the first value and the first plurality of values. The method further includes receiving a first plurality of outputs from the first model. each of the first plurality of outputs is associated with the first value and one of the first plurality of values. Each of the first plurality of outputs is associated with a first feature of a simulated substrate. The method further includes preparing the first plurality of outputs for presentation via a presentation element of a GUI. The presentation element comprises two independent axes. A first axis of the two independent axes corresponding to a first property of the first feature. Preparing the first plurality of outputs for presentation includes facilitating generation of a graphic in the presentation element that visually displays a relationship of the outputs of the first plurality of outputs to the first property of the first feature.

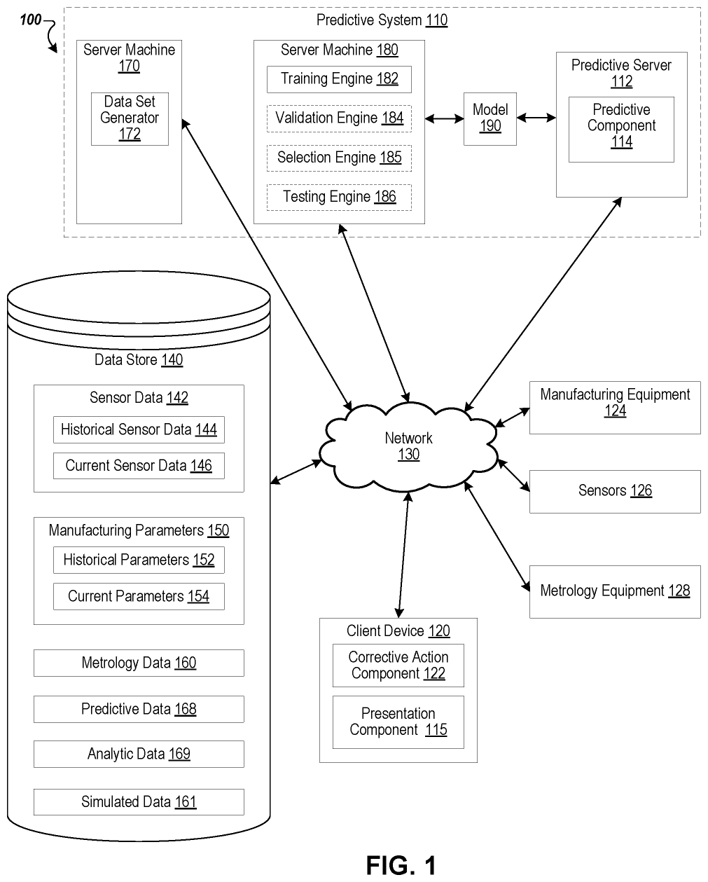

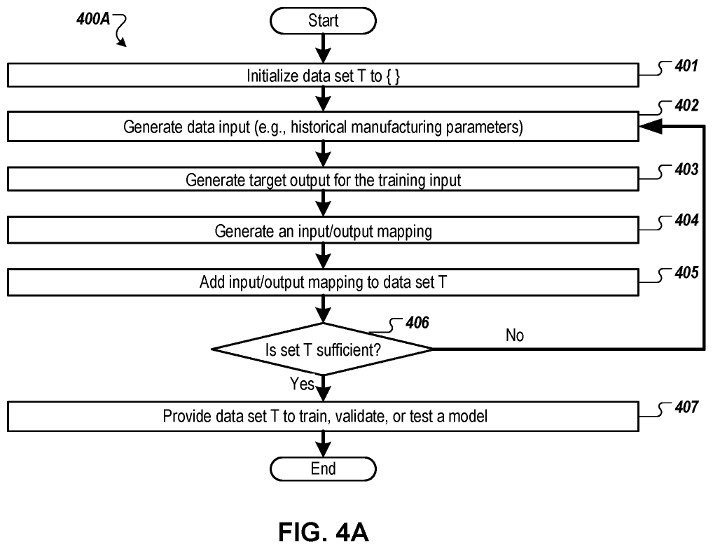

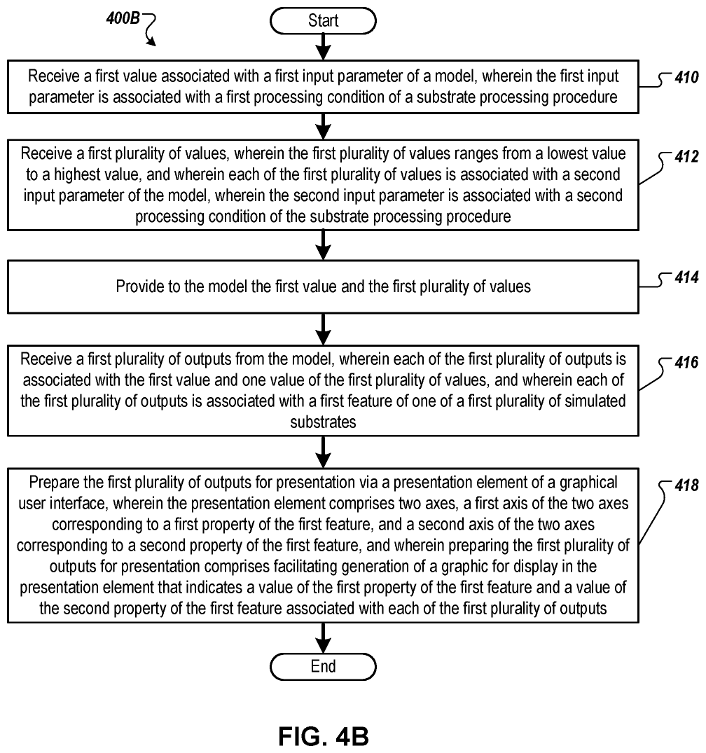

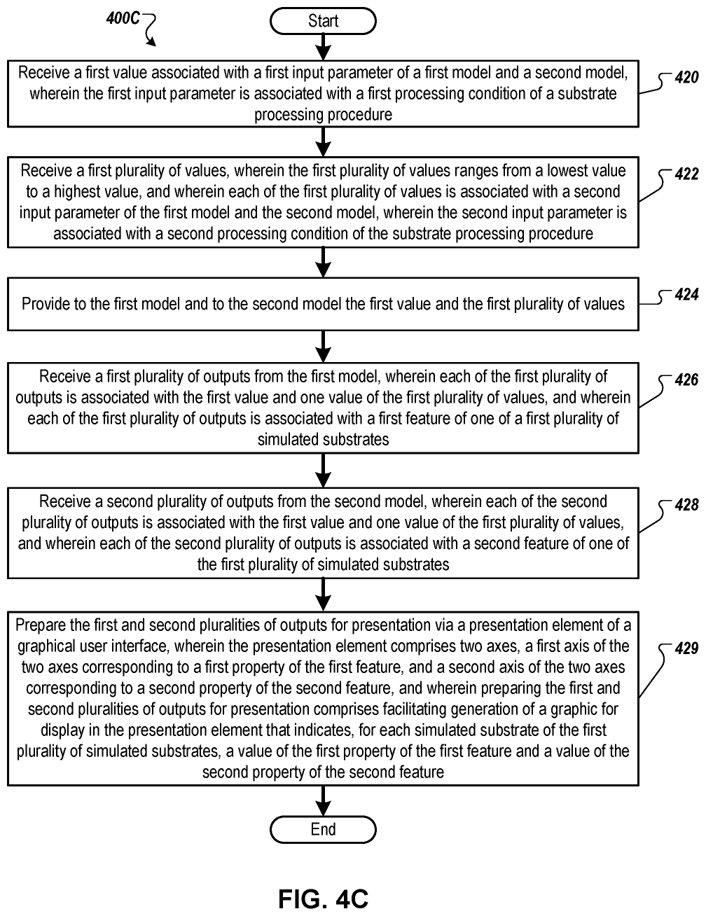

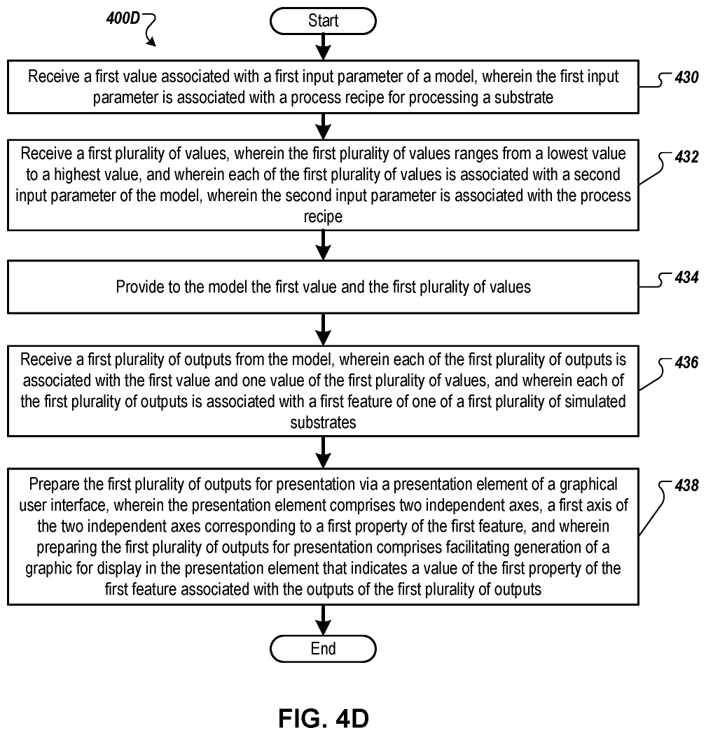

FIG. 1 is a block diagram illustrating an exemplary system 100 (exemplary system architecture), according to some embodiments. The system 100 includes a client device 120, manufacturing equipment 124, sensors 126, metrology equipment 128, a predictive server 112, and data store 140. The predictive server 112 may be part of predictive system 110. Predictive system 110 may further include server machines 170 and 180. Client device 120 may include presentation component 115, which may execute one or more of the methods described in connection with FIGS. 4A-D. In some embodiments, presentation component 115 may be included, wholly or in part, in a different component of system 100, such as predictive server 112, server machine 170, or server machine 180.

In some embodiments, manufacturing equipment 124 (e.g., cluster tool) is part of a substrate processing system (e.g., integrated processing system). The manufacturing equipment 124 includes one or more of a controller, an enclosure system (e.g., substrate carrier, front opening unified pod (FOUP), FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers, a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber. In some embodiments, manufacturing equipment 124 includes components of substrate processing systems. In some embodiments, manufacturing equipment 124 is used to produce one or more products (e.g., substrates, semiconductors, wafers, etc.). In some embodiments, manufacturing equipment 124 is used to produce one or more components to be used in substrate processing systems. In some embodiments, manufacturing equipment 124 is used to produce and/or includes a bonded metal plate structure (e.g., showerhead to be used in a processing chamber of a substrate processing system).

Sensors 126 may provide sensor data 142 associated with manufacturing equipment 124 (e.g., associated with producing, by manufacturing equipment 124, corresponding products, such as wafers). Sensor data 142 may be used for equipment health and/or product health (e.g., product quality), for example. Manufacturing equipment 124 may produce products following a recipe or performing runs over a period of time. In some embodiments, sensor data 142 may include values of one or more of temperature (e.g., heater temperature), spacing (SP), pressure, High Frequency Radio Frequency (HFRF), voltage of Electrostatic Chuck (ESC), electrical current, flow (e.g., of one or more gases), power, voltage, etc. Sensor data 142 may include historical sensor data 144 and current sensor data 146. Historical sensor data 144 may be related to historical processes, e.g., manufacturing or processing runs associated with previously produced products (e.g., substrates, semiconductor wafers, or the like). Historical sensor data 144 may be utilized as training data for training one or more models, e.g., model 190. Model 190 may be a machine learning model, a physics-based model, a statistical model, and so on. Current sensor data 146 may be associated with an operation that is not historical, e.g., a substrate currently undergoing processing, a substrate that recently underwent processing, a target substrate of interest, or the like.

Manufacturing equipment 124 may be configured according to manufacturing parameters 150. Manufacturing parameters 150 may be associated with or indicative of parameters such as hardware parameters (e.g., settings or components (e.g., size, type, etc.) of the manufacturing equipment 124) and/or process parameters of the manufacturing equipment. Manufacturing parameters 150 may include historical manufacturing data (historical parameters 152) and/or current manufacturing data (current parameters 154). Manufacturing parameters 150 may be indicative of input settings to the manufacturing device (e.g., heater power, gas flow, etc.). Sensor data 142 and/or manufacturing parameters 150 may be provided while the manufacturing equipment 124 is performing manufacturing processes (e.g., equipment readings may be made while processing products/substrates). Sensor data 142 may be different for each product (e.g., each wafer). Manufacturing parameters 150 may be the same or substantially the same (e.g., excluding metadata or the like) for a family of products (e.g., a product design, a processing recipe, etc.). Historical parameters 152 may be related to historical processes, e.g., manufacturing or processing runs associated with previously produced products (e.g., substrates, semiconductor wafers, or the like). Historical parameters 152 may be utilized as training data for training one or more models, e.g., model 190. Model 190 may be a machine learning model, a physics based model, or a statistical model in embodiments. Current parameters 154 may be associated with an operation that is not historical, e.g., a substrate currently undergoing processing, a substrate that recently underwent processing, a target substrate of interest, or the like.

Metrology data 160 may include measurements of properties of products produced by manufacturing equipment 124. Historical sensor data 144, historical parameters 152, and metrology data 160 may be associated with produced substrates. Metrology data 160 may include data indicating associations between sets of historical and/or metrology data, e.g., sets of data corresponding to the same produced substrate. Metrology data 160 may include measured and/or predicted metrology (e.g., virtual metrology) associated with any substrate property of interest. Metrology data 160 may include data corresponding to product thickness, resistivity, sheet resistance (e.g., electrical resistivity of a thin film in a direction parallel to a plane of the film), critical dimension (CD, e.g., width of a feature), line width, feature depth, side wall height, or the like. Metrology data 160 may include multi-point metrology data, e.g., a feature (such as thickness) may be measured at multiple points of a substrate, e.g., various locations distributed throughout the spatial extent of the substrate.

In some embodiments, sensor data 142, metrology data 160, and/or manufacturing parameters 150 may be processed (e.g., by the client device 120 and/or by the predictive server 112). Processing of sensor data 142 may include generating attributes (e.g., data features, vectors, feature vectors, etc.). In some embodiments, the attributes are a pattern in the sensor data 142, metrology data 160, and/or manufacturing parameters 150 (e.g., slope, width, height, peak, etc.) or a combination of values from the sensor data 142, metrology data 160, and/or manufacturing parameters 150 (e.g., power derived from voltage and current, etc.). Sensor data 142 may include attributes and the attributes may be used by predictive component 114 for performing signal processing and/or for obtaining predictive data 168, possibly for performance of a corrective action. Predictive data 168 may be any data associated with predictive system 110, e.g. predicted metrology data of a substrate, predicted properties of a substrate, predicted performance of a substrate or of manufacturing equipment 124, or the like.

Each instance (e.g., set) of sensor data 142 may correspond to a product (e.g., a wafer), a set of manufacturing equipment, a type of substrate produced by manufacturing equipment, a combination thereof, or the like. Each instance of metrology data 160 and manufacturing parameters 150 may likewise correspond to a product, a set of manufacturing equipment, a type of substrate produced by manufacturing equipment, a combination thereof, or the like. The data store may further store information associating sets of different data types, e.g. information indicative that a set of sensor data, a set of metrology data, and/or a set of manufacturing data are all associated with the same product, manufacturing equipment, type of substrate, etc.

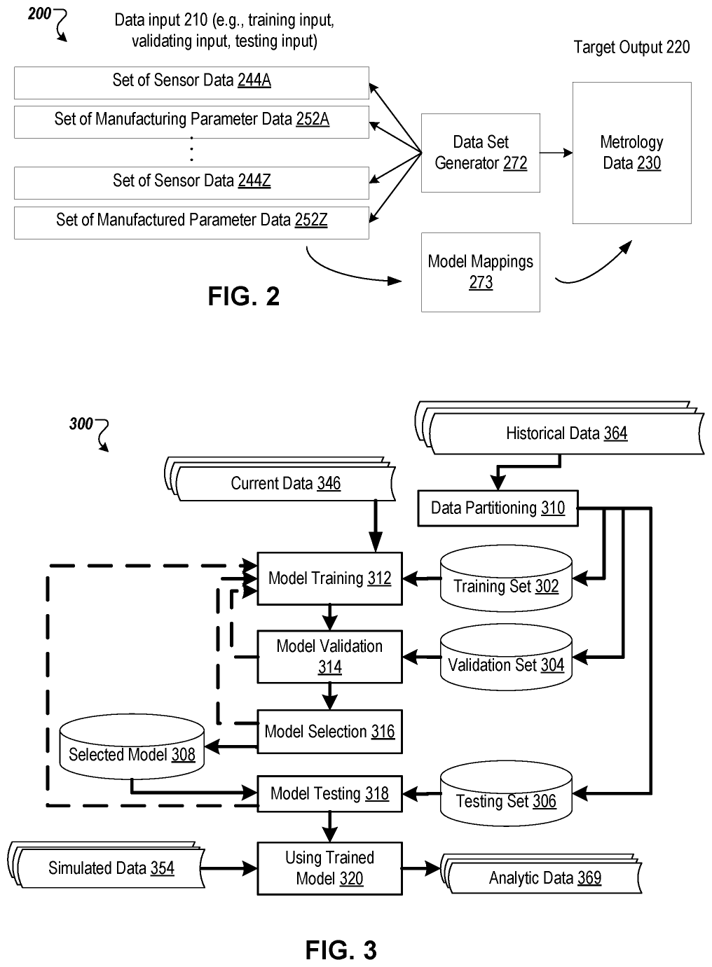

In some embodiments, predictive system 110 may generate predictive data 168 using machine learning (e.g., target output comprising data indicative of a manufacturing fault provided in predictive system 110, etc.). In some embodiments, predictive system 110 may generate predictive data 168 using physics-based modeling. In some embodiments, predictive system 110 may generate predictive data 168 using statistical modeling. Two or more of these techniques may also be combined. Operations of predictive system 110 are discussed in greater detail in connection with FIGS. 2-3 and 4A-D.

Client device 120, manufacturing equipment 124, sensors 126, metrology equipment 128, predictive server 112, data store 140, server machine 170, and server machine 180 may be coupled to each other via a network 130 for generating predictive data 168. Predictive data 168 may be used in performing corrective actions. Predictive data 168 may be used in displaying model learning and/or relationships between inputs (e.g., manufacturing parameters) and outputs (e.g., substrate properties, processing chamber performance, etc.) of one or more models. Predictive data 168 may be used in presenting one or more indications of model learning and/or relationships between inputs and outputs of one or more models.

In some embodiments, network 130 is a public network that provides client device 120 with access to predictive server 112, data store 140, and/or other publically available computing devices. In some embodiments, network 130 is a private network that provides client device 120 access to manufacturing equipment 124, sensors 126, metrology equipment 128, data store 140, and/or other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), personal area networks, routers, hubs, switches, server computers, cloud computing networks, and/or a combination thereof.

Client device 120 may include one or more computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. In some embodiments, the corrective action component 122 transmits the indication to the predictive system 110, receives output (e.g., predictive data 168) from predictive system 110, determines a corrective action based on the output, and causes the corrective action to be implemented. In some embodiments, presentation component 115 of client device 120 may perform one or more actions associated with providing information indicative of model learning and/or visualizations of input to output dependencies to a user. Presentation component 115 may generate one or more plots, may perform calculations or cause calculations to be performed by another device (e.g., predictive server 112), may receive user instruction via a GUI associated with presenting information to the user, or the like.

In some embodiments, predictive system 110 may further include a predictive component 114. Predictive component 114 may take data retrieved from model 190 to generate predictive data 168. In some embodiments, predictive component 114 provides predictive data 168 to client device 120, and client device 120 causes a corrective action (e.g., including displaying predictive data 168 for a user) via corrective action component 122 in view of predictive data 168. In some embodiments, corrective action component 122 obtains an indication of data to be included in a corrective action or presentation element, retrieves the data (e.g., from data store 140, by supplying one or more inputs from model 190 and receiving one or more outputs from model 190, by providing instructions to predictive component 114 or predictive system 110 and receiving output, etc.), and displays the data for a user. In some embodiments, corrective action component 122 may store data (e.g., store one or more plots, one or more setting parameters, etc.), for example via data store 140 as analytic data 169. Analytic data 169 may include any data which is produced as output by any methods described herein, such as methods described in connection with FIGS. 3 or FIGS. 4A-D.

In some embodiments, predictive server 112 may store output (e.g., predictive data 168) of the trained model(s) 190 in data store 140 and client device 120 may retrieve the output from data store 140. In some embodiments, corrective action component 122 receives an indication of a corrective action from predictive system 110 and causes the corrective action to be implemented (e.g., causes data to be displayed to a user). Each client device 120 may include an operating system that allows users to one or more of generate, view, or edit data (e.g., indication associated with manufacturing equipment 124, corrective actions associated with manufacturing equipment 124, etc.).

In some embodiments, metrology data 160 corresponds to historical property data of products (e.g., produced using manufacturing parameters associated with historical sensor data and historical manufacturing parameters) and predictive data 168 is associated with predicted property data (e.g., of products to be produced or that have been produced in conditions recorded by current sensor data 144 and/or current parameters 154). In some embodiments, predictive data 168 is predicted metrology data (e.g., virtual metrology data) of the products to be produced or that have been produced according to conditions recorded as current sensor data and/or current manufacturing parameters. In some embodiments, predictive data 168 is or includes an indication of abnormalities (e.g., abnormal products, abnormal components, abnormal manufacturing equipment, abnormal energy usage, etc.) and/or one or more causes of the abnormalities. In some embodiments, predictive data 168 includes an indication of change over time or drift in some component of manufacturing equipment 124, sensors 126, metrology equipment 128, and the like. In some embodiments, predictive data 168 includes an indication of an end of life of a component of manufacturing equipment 124, sensors 126, metrology equipment 128, or the like.

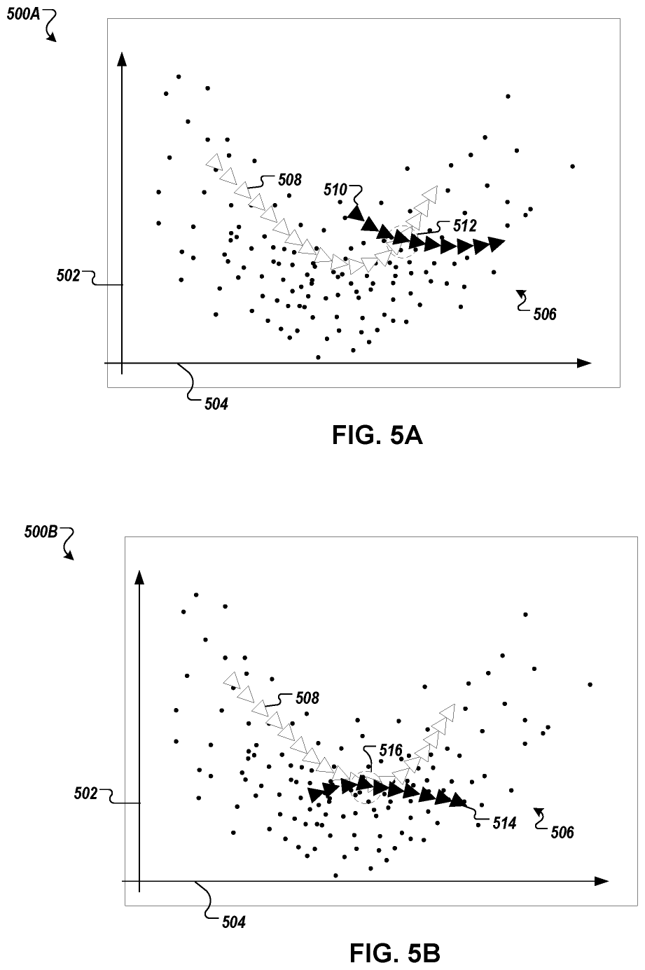

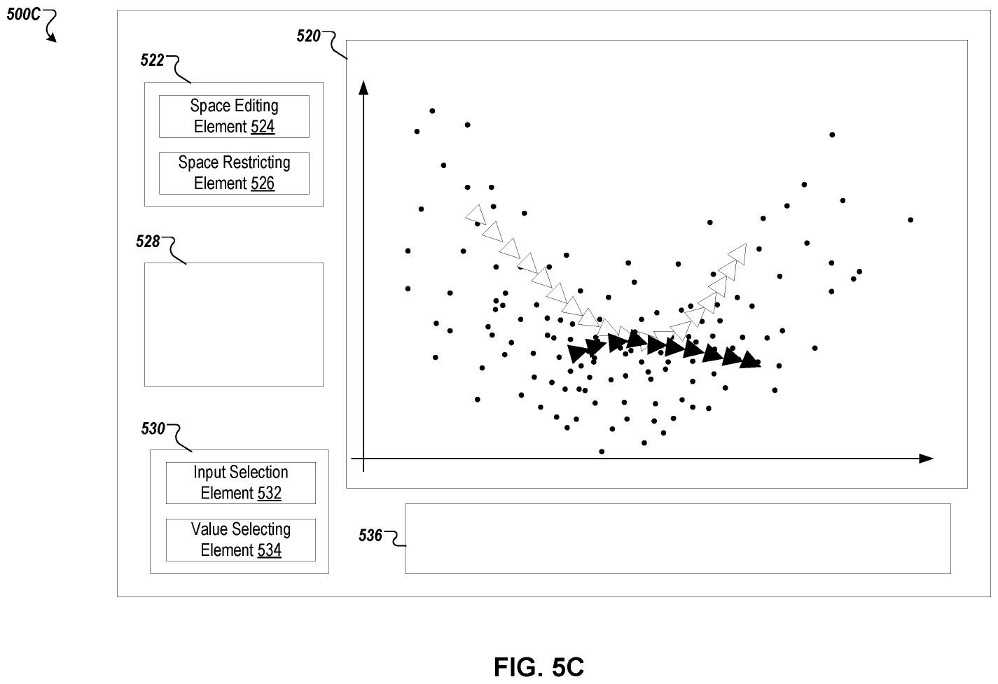

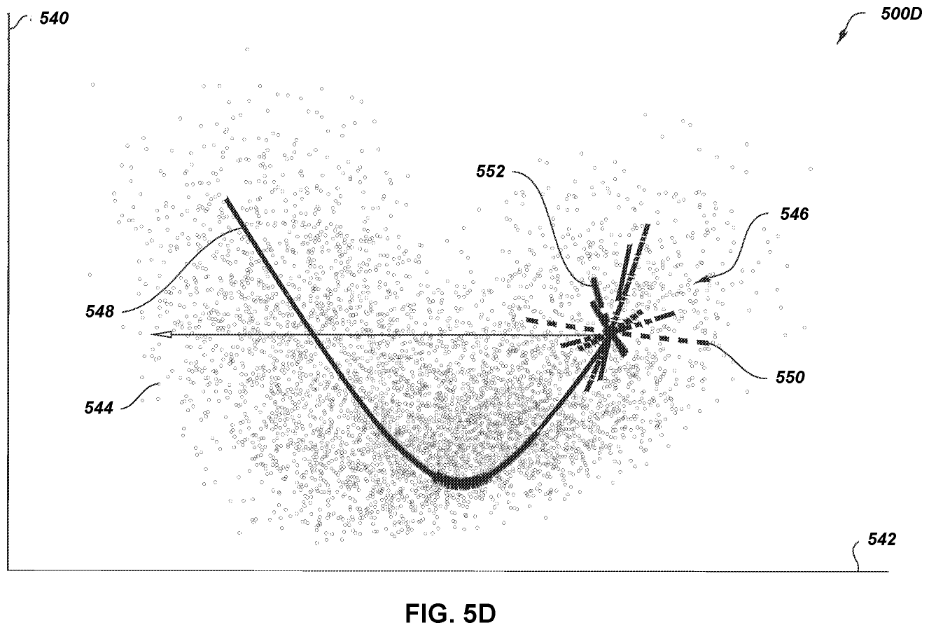

In some embodiments, one or more outputs of model 190 may be provided to presentation component 115. Presentation component 115 may generate an indication of model learning, model input/output mappings and/or associations, or the like. Output of presentation component 115 (e.g., plots, GUI elements, etc.) may be similar to those discussed in connection with FIGS. 5A-C. In some embodiments, presentation component 115 may generate an indication of the extent of output space of model 190. For example, simulated data 161 may be provided as multiple data sets to model 190. Simulated data 161 may span an input space or a portion of an input space of model 190. For example, simulated data 161 may include data associated with a number of inputs of model 190. Simulated data 161 may include data sets with values for inputs of model 190 ranging from minimum input values (e.g., minimum values of an input for which the model is trained, minimum values of an input for which the model generates output meeting a threshold confidence level, or the like) to maximum input values (e.g., according to similar constraints as the minimum input values). In some embodiments, simulated data 161 may be generated to span an input space of model 190. For example, simulated data 161 may be generated in a grid over the dimensions of the input space (e.g., a first input may take one of several values, a second input may take one of a second list of values, a third input may take one of a third list of values, in all combinations to generate a multi-dimensional grid spanning an input space of model 190). Sets of inputs (e.g., sets approximately spanning the input space of the model) may be provided to the model. Outputs of the model may be stored.

In some embodiments, presentation component 115 may generate an indication of the extent of output space of model 190. Model 190 may be provided with a set of inputs that approximately span the input space of model 190 (e.g., the space of input values for which the model is trained, the span of input values for which the model generates output meeting a threshold confidence condition, or the like). Model 190 may be provided with randomly sampled sets of inputs. For example, a distribution of training inputs may be generated (e.g., a distribution of values provided during training as a first input, a second distribution of values provided during training as a second input, etc.). A random distribution of simulated training inputs may be generated that conforms to the statistical spread of training data for the model. In some embodiments, a random sampling of input data within the input space, within a portion of the input space, or the like may be generated. In some embodiments, a random sampling of input data may be distributed according to a metric other than the distribution of inputs of the training data (e.g., a Gaussian, Lorenzian, or other distribution shape may be generated based on a minimum and maximum input value for one or more inputs). Each of the sets of inputs (e.g., that together approximately span the input space of the model) may be provided to the model. Outputs of the model may be stored.

In some embodiments, a model (e.g., model 190) may generate a single output from a set of inputs. In some embodiments, a model (e.g., model 190) may generate a plurality of outputs from a set of inputs. In some embodiments, a model may generate several outputs directed at a single feature from a set of inputs (e.g., thickness measurements from a number of locations of a substrate, etc.). In some embodiments, a model may generate several outputs directed at multiple features from a set of inputs (e.g., thickness and resistivity measurements from a number of locations of a substrate). Herein, a model will generally be described as a model that receives a set of inputs and generates as output a number of values directed as a single feature (e.g., predicted measurements of a feature at multiple locations of a substrate). Models that operate differently, e.g., models that produce as output a single output value, models that produce as output values directed at multiple features and/or properties of those features, etc., are within the scope of this disclosure. In some embodiments, an ensemble model including multiple models may be utilized, e.g., one set of inputs may be provided to a model and two sets of outputs will be generated (e.g., each set of outputs directed at a different feature). Herein, no distinction will be made between an ensemble model that generates indications of multiple features and two separate models that generate indications of multiple features, e.g., providing a set of inputs to a model or receiving output from a model may be interpreted in some applications as operations associated with a sub-model of an ensemble model.

In some embodiments, output of one or more models may be presented to a user. Each set of input conditions (e.g., of the input conditions that approximately span the input space, of the input conditions that span a portion of the input space, etc.) may correspond to one or more outputs. An indication of outputs of each set of input conditions may be presented on a plot. The plot may approximately represent the span of an output space of model 190.

In some embodiments, each set of inputs (e.g., of the inputs approximately spanning the input space of one or more models) may correspond to one plotted point on a scatter plot. In some embodiments, the axes of the plot (e.g., the horizontal (“x”) and vertical (“y”) axes of a two-dimensional scatter plot, the two horizontal and one vertical axes of a three dimensional scatter plot, etc.) may correspond to outputs of the one or more models. In some embodiments, axes of the plot may correspond to properties of features associated with outputs of the one or more models. Features may include any feature of interest of a substrate. Features may include measurable metrology features of a substrate. Features may include thickness, resistivity, sheet resistance, refractive index, extinction coefficient, critical dimension, line width, depth, side wall height, etc. Properties may include statistical metrics of features, e.g., several measurements of a feature (e.g., simulated measurements at various locations of a substrate, simulated metrology measurements, etc.) may be provided as output from model 190, and properties of that feature may include average value, median value, standard deviation, uniformity, interquartile range, kurtosis, skew, or any other statistical metric describing the spread of feature values. In some embodiments, features or properties of features may include a subset of values output by the model. For example, values of a feature near the outer edge of a wafer, values of a feature within an angular range or radial range, values of a feature near the center of a wafer, or the like may be of interest. A feature or a property of a feature may include a spatial combination of feature measurements, a statistical combination of feature measurements (e.g., average of a portion of measurement values, such as the lowest quarter, median half, etc.), or the like.

In some embodiments, a first axis of the plot of the outputs may correspond to a first property of a first feature (as an illustrative example, average thickness). The second axis of the plot may correspond to a second property of the first feature (continuing the illustrative example, standard deviation of simulated thickness measurements). Each set of input conditions may generate a point on a scatter plot with a specific value corresponding to the first axis and a specific value corresponding to the second axis (continuing the illustrative example, each set of input conditions may generate a simulated substrate with an average thickness and a standard deviation of thickness measurements, and a point may be placed on the plot at the appropriate location for each set of inputs, thus visually mapping out the extent of the input space of the model into the two-dimensional output space represented by the plot). In some embodiments, a three dimensional scatter plot may be generated including a third axis corresponding to a third property of the first feature.

In some embodiments, a first axis of the plot of the outputs may correspond to a first property of a first features (as an illustrative example, average thickness). The second axis of the plot may correspond to a second property of a second feature (continuing the illustrative example, standard deviation of simulated resistivity measurements). The second property may be the same property or a different property from the first property. In some embodiments, the feature associated with the second axis of the plot may be generated by a second model. Each set of input conditions may generate a point on a scatter plot with a specific value corresponding to the first axis and a specific value corresponding to the second axis (continuing the illustrative example, each set of input conditions may generate an average thickness value and a resistivity standard deviation value, and a data point may be plotted on the plot at a position corresponding to the average thickness and the resistivity standard deviation). In some embodiments, a three dimensional scatter plot may be generated including a third axis. The third axis may correspond to a third property of the first feature, a third property of the second feature, a third property of a third feature, etc.

In some embodiments, outputs associated with the sets of inputs that span the input space of one or more models (e.g., approximately span the input space, span a portion of the input space, etc.) may be displayed on a plot as scattered points, e.g., a background “cloud” indicative of the extent of the output space of the one or more models in the plotted dimensions (e.g., associated with the plotted features and properties of features).

In some embodiments, a set of inputs of interest (e.g., a baseline set of inputs, a central set of inputs, etc.) may be provided to the one or more models. The one or more models may generate an output associated with the baseline set of inputs. The output may be displayed on the plot, e.g., along with the cloud of scattered plots representing the span of output space of the one or more models.

In some embodiments, a series of sets of inputs of interest may be provided to the one or more models. For example, the series of sets of inputs may include a baseline set of inputs. The series of sets of inputs may further include sets of inputs where one input is varied compared to the baseline set of inputs. For example, sets of inputs may be provided to the one or more models where all inputs except the one are held at their baseline values, and values associated with the one input are varied between the sets of inputs. The values associated with the one input may be varied from a minimum value to a maximum value. The minimum value and the maximum value may be associated with the extent of an input space of the model, an extent of an input space measured orthogonal to the baseline values, a confidence interval (e.g., an input space wherein outputs meet a threshold confidence metric value condition), a subset of one of these intervals, or the like. The values associated with the one input may be varied systematically or randomly. The values associated with the one input may be varied in even increments, increments according to some function (e.g., logarithmically spaced), increments according to some distribution (e.g., a Gaussian distribution, a distribution defined by the set of training data associated with the one or more models, etc.), or the like. The set of outputs may depict the learning of the effect of varying the one input value on the output metrics associated with the plot (e.g., associated with the two or three axes of the plot). Visual depictions of the outputs associated with the series of sets of inputs may include a visual distinction between the output associated with the minimum value of the one input and the maximum value of the one input. For example, an output point associated with the minimum input value may be colored green and an output point associated with the maximum input value may be colored red, an output point associated with the minimum input value may be of a different (e.g., unique in the plot) shape than the output point associated with the maximum input value, each of the output points may be presented in the shape of an arrowhead pointed toward the next (e.g., the next higher value of the input) output point, or the like. The outputs associated with the series of sets of input values may generate a curve on the plot demonstrating learning of the model, demonstrating the effect of varying the one variable on output of the model, etc. In some embodiments, points of the curve may be distinguished from each other, e.g., a presented data points associated with the lowest value of the varied input value may be visually distinguished form a presented data point associated with the highest value of the varied input value.

In some embodiments, multiple series of sets of inputs may be provided to the one or more models. For example, each series of sets of inputs may constrain all input values but one to a baseline value, while one input value (e.g., one input value for each series) may be varied as described above. Each series may, for example, be plotted in a visually distinct way, e.g., using a different color, different shape, different pattern, or the like of visual representation of the output data. In some embodiments, each series of sets of inputs may generate a curve of output data points. Each series of sets of inputs may be plotted and generate a curve indicating model learning associated with varying the one input associated with that series. Each curve associated with a series of sets of inputs may meet and/or cross at an outpoint point associated with the baseline set of inputs.

In some embodiments, presentation component 115 may update a plot based on user selection, e.g., of settings, of parameters, of baseline input conditions, or the like. A user may be able to navigate the input and/or output space via a GUI, e.g., associated with client device 120. Operation of a GUI, operation of presentation component 115, example plots, and the like, are discussed in more detail in connection with FIGS. 5A-C.

Performing manufacturing processes that result in defective products can be costly in time, energy, products, components, manufacturing equipment 124, the cost of identifying the defects and discarding the defective product, etc. By inputting sensor data 142 (e.g., measurements of conditions in a processing chamber) and/or manufacturing parameters 150 (e.g., processing recipe parameters) into model 190 (e.g., a machine learning model), receiving output of predictive data 168, and performing a corrective action based on predictive data 168, system 100 can have the technical advantage of avoiding the cost of producing, identifying, and discarding defective products.

In some embodiments, the learning (e.g., one or more aspects of input/output mapping of the model) of a model 190 (e.g., machine learning model) may be subject to additional testing, verification, or the like. In some embodiments, one or more aspects of associations between input and output of a model may be displayed for review, examination, verification, utilization, for updating process parameters, for design of new processing recipes, or the like.

In some embodiments, a user may choose to implement a model, e.g., a user may determine what actions are to be taken based on the output of a model. In some embodiments, the user may not be involved in the development of the model (e.g., a customer of a seller of the model), may not be an expert in modeling techniques (e.g., may be an engineer or technician, not an expert on model building, model training, or the like), may not have experience with utilizing model output (e.g., may have developed an intuitive understanding, may rely on internal knowledge or past experience, etc.), or the like. A user may be presented with output of a model in a conventional format and be unable to conceptualize the results as an indication of connections, mappings, or learnings (e.g., input/output mappings) learned by the model (e.g., during model training). A user may be unwilling to utilize a model that the user doesn't understand, may not trust a model that does not generate results in line with the user's understanding, or the like. A model that has learning associated with the model demonstrated to a user in an understandable way may have advantages of being trusted by the user, being verified by the user, etc. A model that is trusted by a user may be utilized more fully, may be allowed to more completely improve a processing procedure or the operations of a processing facility, etc.

Performing manufacturing processes that result in failure of the components of the manufacturing equipment 124 can be costly in downtime, damage to products, damage to equipment, express ordering replacement components, etc. By inputting sensor data 142 (e.g., measurements of conditions in a processing chamber) and/or manufacturing parameters 150 (e.g., recipe parameters of a processing recipe) to model 190 (e.g., a machine learning model, a physics-based model, a statistical model, etc.) and receiving output of predictive data 168, and performing corrective actions (e.g., predicted operational maintenance, such as replacement, processing, cleaning, etc. of components) based on the predictive data 168, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, sensors 126, metrology equipment 128, and the like, may provide indications of degrading components. Monitoring the performance of a component (e.g., a substrate support) over time may extend the component's operational lifetime, for instance if, after a standard replacement interval passes, measurements indicative that the component may still perform well (e.g., performance above a threshold) for a time (e.g., until the next planned maintenance event).

In some embodiments, there may be a cost associated with performing an action recommended by a model. For example, a model may suggest that a component is failing and/or is to be maintained before the component is scheduled to be replaced/maintained (e.g., the model may generate output indicating that a component is to be replaced or maintained). It may be costly in terms of down time, cost of replacement components, shortening of active run time (e.g., green time), etc., to perform the recommended maintenance. A user may elect to avoid the cost of performing the action if the user is not familiar with learning, associations, mappings, or the like of the model. In some embodiments, avoiding the cost of performing the corrective action may incur greater cost, e.g., the component may fail, which may cause loss of product, costly unscheduled downtime, damage to other components of the system, etc. In some embodiments, a machine learning model may recommend (e.g., may generate output indicative of) delaying maintenance (e.g., a component may be performing above scheduled expectations). The system may be less costly to operate if a user elects to follow instructions (e.g., perform a corrective action such as updating a maintenance schedule) and delay maintenance (e.g., by extending active processing time). Generating a model that a user trusts may have benefits in terms of cost of operation of a manufacturing system due to the user taking actions responsive to predicted component lifetimes of components of the manufacturing system.

Manufacturing parameters may be suboptimal for producing products which may have costly results of increased resource (e.g., energy, coolant, gases, etc.) consumption, increased amount of time to produce the products, increased component failure, increased proportion of defective products produced, etc. By inputting the sensor data 142 into a trained model 190 (e.g., a machine learning model, a physics-based model, etc.), receiving an output of predictive data 168, and performing (e.g., based on predictive data 168) a corrective action of updating manufacturing parameters (e.g., setting optimal manufacturing parameters), system 100 can have the technical advantage of using optimal manufacturing parameters (e.g., hardware parameters, process parameters, optimal design) to avoid costly results of suboptimal manufacturing parameters. In some embodiments, a user may elect to perform a recommended corrective action. A user's choice of whether to perform a corrective action may be based on the user's trust of the model, the user's understanding of the operation of the model, a user's understanding of the learning of the model, or the like. Methods and systems disclosed herein may enable a user to develop an understanding of operations and learning of a model. Methods and systems disclosed herein may facilitate a user performing recommended corrective actions associated with a manufacturing system, e.g., updating manufacturing parameters, processing recipes, or the like. This may increase the efficiency of the manufacturing system, reduce cost of operation, etc.

Corrective action may be associated with one or more of Computational Process Control (CPC), Statistical Process Control (SPC) (e.g., SPC on electronic components to determine process in control, SPC to predict useful lifespan of components, SPC to compare to a graph of 3-sigma, etc.), Advanced Process Control (APC), model-based process control, preventative operative maintenance, design optimization, updating of manufacturing parameters, updating manufacturing recipes, feedback control, machine learning modification, or the like.

In some embodiments, the corrective action includes providing an alert (e.g., an alarm to stop or not perform the manufacturing process if predictive data 168 indicates a predicted abnormality, such as an abnormality of the product, a component, or manufacturing equipment 124). In some embodiments, the corrective action includes providing feedback control (e.g., modifying a manufacturing parameter responsive to the predictive data 168 indicating an abnormality). In some embodiments, the corrective action includes updating a processing recipe (e.g., modifying one or more manufacturing parameters based on the predictive data 168). In some embodiments, performance of the corrective action includes causing updates to one or more manufacturing parameters. In some embodiments, performance of the corrective action includes causing updates to one or more calibration tables and/or equipment constants (e.g., a set point provided to a component may be adjusted by a value across a number of process recipes, for example voltage applied to a heater may be increased by 3% for all processes using the heater).

Manufacturing parameters may include hardware parameters (e.g., a history of replacing components, an indication that the manufacturing system is using certain components, an indication of updates to processing such as replacing a processing chip or updating firmware, etc.) and/or process parameters (e.g., temperature, pressure, flow, rate, electrical current, voltage, gas flow, lift speed, etc.). In some embodiments, the corrective action includes causing preventative operative maintenance (e.g., replace, process, clean, etc. components of the manufacturing equipment 124). In some embodiments, the corrective action includes causing design optimization (e.g., updating manufacturing parameters, manufacturing processes, manufacturing equipment 124, etc. for an optimized product). In some embodiments, the corrective action includes a updating a recipe (e.g., manufacturing equipment 124 to be in an idle mode, a sleep mode, a warm-up mode, etc.). In some embodiments, a corrective action (e.g., recommended by model 190, performed by client device 120, performed by presentation component 115, or the like) may include providing an alert to a user (e.g., preparing data for presentation to a user).

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

Predictive server 112 may include predictive component 114. Predictive component 114 may be used to produce predictive data 168. In some embodiments, predictive component 114 may receive current sensor data 146, and/or current parameters 154 (e.g., receive from the client device 120, retrieve from the data store 140) and generate output for performing corrective action associated with manufacturing equipment 124 based on the current data.

Manufacturing equipment 124 may be associated with one or more machine leaning models, physics-based models, statistical models, and so on, e.g., model 190. Machine learning models and other models associated with manufacturing equipment 124 may perform many tasks, including process control, classification, performance predictions, etc. Model 190 may be trained using data associated with manufacturing equipment 124 or products processed by manufacturing equipment 124, e.g., sensor data 142 (e.g., collected by sensors 126), manufacturing parameters 150 (e.g., associated with process control of manufacturing equipment 124), metrology data 160 (e.g., generated by metrology equipment 128), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning describes a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., recognizing structures of a substrate such as gates, masks, etc.); and the fourth layer may generate a classification output. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

In some embodiments, predictive component 114 may use one or more models 190 to determine the output for performing the corrective action based on current data. Model 190 may be a single model, an ensemble model, or a collection of models used to process data. Model 190 may include one or more physics-based digital twin models, supervised machine learning models, unsupervised machine learning models, semi-supervised machine learning models, statistical models, etc.

In some embodiments, client device 120 may provide current sensor data 146 (e.g., sensor data of interest) to predictive system 110. In some embodiments, presentation component 115 may provide simulated data 161 to predictive system 110. Simulated data 161 may include data correlated to sensor data 142, manufacturing parameters 150, etc. Simulated data 161 may be or include user input (e.g., input via a GUI of client device 120). Simulated data may be provided to model 190 as input, e.g., as input of interest, to generate (e.g., via presentation component 115) a graphical representation of model learning, model knowledge, model mappings/associations between inputs and outputs, etc.

In some embodiments, data indicative of properties of a substrate to be produced using a manufacturing system (e.g., predictive data) is provided to a model such as a trained machine learning model (e.g., model 190). The model may be trained to output data indicative of a corrective action to produce a substrate with different characteristics. In some embodiments, data indicative of predictive properties of a substrate produced using manufacturing equipment 124, and metrology data of a substrate produced with that substrate support are provided as input to a t model (e.g., model 190). The model may predict underlying causes for differences between predicted and measured data (e.g., manufacturing fault, component aging or drift, etc.).

Historical sensor data 142, historical parameters 152, and/or metrology data 160 may be used in combination with current sensor data 146 and current parameters 154 to detect drift, changes, aging, etc. of components of manufacturing equipment 124. Sensor data 142 monitored over time may contain information indicative of changes to one or more components of manufacturing equipment 124, e.g., due to aging, drift, component failure, deposition or removal of material, etc. Predictive component 114 may use combinations and comparisons of these data types to generate predictive data 168. In some embodiments, predictive data 168 includes data predicting the lifetime of components of manufacturing equipment 124, sensors 126, etc. Presentation component 115, used in combination with predictive system 110, data store 140, etc., may provide a representation of learning of model 190.

In some embodiments, predictive component 114 receives data, such as sensor data 142, manufacturing parameters 150, metrology data 160, etc., and may perform pre-processing such as extracting patterns in the data or combining data to new composite data. Predictive component 114 may then provide the data to model 190 as input. Model 190 may include a physics-based digital twin model, accepting as input sensor data 142, manufacturing parameters 150, simulated data 161, or the like. It may include a trained machine learning model, a statistical model, etc., configured to further process data associated with properties of a substrate, performance of manufacturing equipment 124, etc. Predictive component 114 may receive from model 190 predictive data, indicative of substrate support performance, predicted substrate properties, a manufacturing fault, component drift, or the like. Predictive component 114 may then cause a corrective action to occur (e.g., recommend a corrective action to a user). The corrective action may include sending an alert to client device 120. The corrective action may also include updating manufacturing parameters of manufacturing equipment 124. The corrective action may also include generating predictive data 168, indicative of chamber or instrument drift, aging, or failure.

In some embodiments, a model may be trained and utilized to generate recommended corrective actions, and/or to cause corrective actions (e.g., a model may be operatively coupled to one or more components of manufacturing equipment 124 and output of the model may automatically update future processing parameters or the like). In both the case of a recommended action and the case of an automatically performed corrective action, it may be valuable to provide record of model learning to a user, e.g., for verification of model stability, verification of model mappings, etc. For example, a user may be presented with an alert (e.g., via presentation component 115) describing model learning. In some embodiments, the alert may include a graphical representation of model output for a range of smoothly varying inputs. A user may predict that a smoothly varying input will produce a smoothly varying output. A user may verify that the model has learned input/output associations that the user trusts, and the user may continue to utilize the model, may perform the recommended corrective action, etc.

Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, analytic data 169, simulated data 161, metrology data 160, and predictive data 168. Sensor data may include sensor data time traces over the duration of manufacturing processes, associations of data with physical sensors, pre-processed data, such as averages and composite data, and data indicative of sensor performance over time (i.e., many manufacturing processes). Manufacturing parameters 150 and metrology data 160 may contain similar features. Predictive data 168 may include data output by predictive system 110. Analytic data 169 may include data (e.g., plots, visualizations, etc.) output by presentation component 115 (e.g., for further analysis). Simulated data 161 may include similar features to one or more of sensor data 142 and/or manufacturing parameters 150. Simulated data 161 may be provided to model 190, e.g., to generate output for use by presentation component 115. Simulated data 161 may include data ranges (e.g., ranges of values associated with input parameters to model 190). Historical sensor data 144 and/or historical parameters 152 may be utilized for training model 190. Metrology data 160 may be utilized for training model 190, may include predicted metrology data output by model 190, etc. Metrology data 160 may be metrology data of produced substrates, as well as sensor data, manufacturing data, and model data corresponding to those products. Metrology data 160 may be leveraged to design processes for making further substrates. Predictive data 168 may include predictions of metrology data resulting from operation of a substrate support, predictions of component drift, aging, or failure, predictions of component lifetimes, etc. Predictive data 168 may also include data indicative of components of system 100 aging and failing over time.

In some embodiments, predictive system 110 further includes server machine 170 and server machine 180. Server machine 170 includes a data set generator 172 that is capable of generating data sets (e.g., a set of data inputs and a set of target outputs) to train, validate, and/or test model 190. Some operations of data set generator 172 are described in detail below with respect to FIGS. 2 and 4A. In some embodiments, data set generator 172 may partition historical data (e.g., historical sensor data 144, historical metrology data of metrology data 160, historical parameters 152, etc.) into a training set (e.g., sixty percent of the data), a validating set (e.g., twenty percent of the data), and a testing set (e.g., twenty percent of the data). In some embodiments, predictive system 110 (e.g., via predictive component 114) generates multiple sets of attributes (e.g., feature vectors, vectors, etc.). For example a first set of attributes may correspond to a first set of types of sensor data (e.g., from a first set of sensors, first combination of values from first set of sensors, first patterns in the values from the first set of sensors) that correspond to each of the data sets (e.g., training set, validation set, and testing set) and a second set of attributes may correspond to a second set of types of sensor data (e.g., from a second set of sensors different from the first set of sensors, second combination of values different from the first combination, second patterns different from the first patterns) that correspond to each of the data sets.

In some embodiments, server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 using one or more sets of attributes associated with the training set from data set generator 172. The training engine 182 may generate multiple trained models 190, where each trained model 190 corresponds to a distinct set of attributes of the training set (e.g., sensor data from a distinct set of sensors). For example, a first trained machine learning model may have been trained using all attributes (e.g., X1-X5), a second trained machine learning model may have been trained using a first subset of the attributes (e.g., X1, X2, X4), and a third trained machine learning model may have been trained using a second subset of the attributes (e.g., X1, X3, X4, and X5) that may partially overlap the first subset of attributes. Data set generator 172 may receive the output of a trained model (e.g., 190), collect that data into training, validation, and testing data sets, and use the data sets to train a second model. Some or all of the operations of server machine 180 may be used to train various types of models, including physics-based models, supervised machine learning models, unsupervised machine learning models, etc.

The validation engine 184 may be capable of validating a trained model 190 using a corresponding set of features of the validation set from data set generator 172. For example, a first trained model 190 that was trained using a first set of attributes of the training set may be validated using the first set of attributes of the validation set. The validation engine 184 may determine an accuracy of each of the trained models 190 based on the corresponding sets of features of the validation set. The validation engine 184 may discard trained models 190 that have an accuracy that does not meet a threshold accuracy. In some embodiments, the selection engine 185 may be capable of selecting one or more trained models 190 that have an accuracy that meets a threshold accuracy. In some embodiments, the selection engine 185 may be capable of selecting the trained model 190 that has the highest accuracy of the trained models 190.

The testing engine 186 may be capable of testing a trained model 190 using a corresponding set of attributes of a testing set from data set generator 172. For example, a first trained model 190 that was trained using a first set of attributes of the training set may be tested using the first set of attributes of the testing set. The testing engine 186 may determine a trained model 190 that has the highest accuracy of all of the trained models based on the testing sets.

Model 190 may refer to a machine learning model, which may be the model artifact that is created by the training engine 182 using a training set that includes data inputs and corresponding target outputs (correct answers for respective training inputs). Model 190 may additionally or alternatively refer to a statistical model or physics-based model. Patterns in the data sets can be found that map the data input to the target output (the correct answer), and the model 190 is provided mappings that captures these patterns. In some embodiments, model 190 may predict properties of substrates. In some embodiments, model 190 may predict failure modes of manufacturing chamber components.

Model 190 may refer to a trained physics-based model. A trained physics-based model may be configured to find solutions to one or more equations described physical quantities of a processing chamber, such as mass flow (e.g., gas flow), heat transfer equations, fluid dynamics equations, or the like. In some embodiments, assumptions used to generate the physics-based model may not be entirely accurate (e.g., due to imprecise measurements, manufacturing or material defects, mismatches of manufacturing tolerances of components, components aging, drifting, or acting differently than predicted, or the like). Training a physics-based model may correct for one or more of these assumptions that introduces error into the physics-based model, e.g., by allowing one or more parameters of the model to be altered to better fit to training data.

Predictive component 114 may provide input data to a trained model 190 and may run the trained model 190 on the input to obtain one or more outputs. Predictive component 114 may be capable of determining (e.g., extracting) predictive data 168 from the output of the model 190 and may determine (e.g., extract) confidence data from the output that indicates a level of confidence that the predictive data 168 is an accurate predictor of a process associated with the input data for products produced or to be produced, or an accurate predictor of components of manufacturing equipment 124. Predictive component 114 may be capable of determining predictive data 168, including predictions on finished substrate properties and predictions of effective lifetimes of components of manufacturing equipment 124, sensors 126, or metrology equipment 128 based on the output of model 190. Predictive component 114 or corrective action component 122 may use the confidence data to decide whether to cause a corrective action associated with the manufacturing equipment 124 based on predictive data 168. Presentation component 115 may utilize confidence data, e.g., in visually presenting some regions of output space of a model as uncertain (e.g., by showing data in a different color, shape, shade, size, level of transparency, or the like to indicate mode confidence).

The confidence data may include or indicate a level of confidence. As an example, predictive data 168 may indicate the properties of a finished wafer given a set of manufacturing inputs (e.g., current parameters 154), including the use of manufacturing equipment 124. The confidence data may indicate that the predictive data 168 is an accurate prediction for products associated with at least a portion of the input data. In one example, the level of confidence is a real number between 0 and 1 inclusive, where 0 indicates no confidence that the predictive data 168 is an accurate prediction for products processed according to input data and 1 indicates absolute confidence that the predictive data 168 accurately predicts properties of products processed according to input data. Responsive to the confidence data indicating a level of confidence below a threshold level for a predetermined number of instances (e.g., percentage of instances, frequency of instances, total number of instances, etc.) the predictive component 114 may cause the model 190 to be re-trained (e.g., based on current sensor data 146, current manufacturing parameters 150, etc.).

For purpose of illustration, rather than limitation, aspects of the disclosure describe the training of one or more models 190 using historical data and inputting current data into the one or more trained models 190 to determine predictive data 168. In other implementations, a heuristic model or rule-based model is used to determine predictive data (e.g., without using a trained machine learning model). Predictive component 114 may monitor historical data and metrology data 160. Any of the information described with respect to data inputs 210 of FIG. 2 may be monitored or otherwise used in the heuristic or rule-based model.

In some embodiments, the functions of client device 120, predictive server 112, server machine 170, and server machine 180 may be provided by a fewer number of machines. For example, in some embodiments server machines 170 and 180 may be integrated into a single machine, while in some other embodiments, server machine 170, server machine 180, and predictive server 112 may be integrated into a single machine. In some embodiments, client device 120 and predictive server 112 may be integrated into a single machine.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, predictive server 112 may determine the corrective action based on the predictive data 168. In another example, client device 120 may determine the predictive data 168 based on output from model 190 (e.g., a trained machine learning model or a physics-based digital twin model).

In addition, the functions of a particular component can be performed by different or multiple components operating together. One or more of predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

Embodiments of the disclosure may be applied to data quality evaluation, feature enhancement, model evaluation, Virtual Metrology (VM), Predictive Maintenance (PdM), limit optimization, or the like. Embodiments of the disclosure may be applied to any trained modeling system, e.g., may provide model evaluation, model verification, a representation of model learning, or the like, for any machine learning model, any machine learning model associated with manufacturing and/or processing products, any machine learning model that predicts metrology of a wafer to be processed, or the like.

FIG. 2 is a block diagram of an example data set generator 272 (e.g., data set generator 172 of FIG. 1), used to create data sets for a model (e.g., model 190 of FIG. 1), according to some embodiments. A data set generator 272 may be part of server machine 170 of FIG. 1. In some embodiments, system 100 of FIG. 1 includes multiple models. In such cases, each model may have a separate data set generator, or models may share a data set generator. For example, a separate model may be used for each feature of interest of a wafer associated with a set of input data. Depicted in FIG. 2 is a data set generator associated with a machine learning model configured to receive as input sensor data (e.g., current sensor data 146 of FIG. 1), and provide out output predicted metrology of a substrate (e.g., predictive data 168 of FIG. 1). A model (e.g., a machine learning model, a physics-based model, a statistical model, etc.) may be configured to perform one or more of many different tasks. For example, a model may receive sensor data and generate as output feedback control signals for adjusting processing conditions. A model may receive processing parameters and predict performance of a substrate (e.g., predict metrology of the substrate resulting from a process recipe). A model may receive an image (e.g., a block diagram of a target substrate design) and generate a related image (e.g., a realistic image of a simulate substrate). A model may receive an indication of a target product design and may generate as output a process recipe predicted to produce a product of that design. A model may receive measurements of one or more components of a manufacturing system and generate as output a predicted performance of the system. Any of these or many other specific use cases of models (e.g., any machine learning model that maps a set of inputs to one or more outputs, models associated with manufacturing, models associated with substrate processing, models associated with semiconductor wafers, etc.) may benefit from methods and systems described herein, e.g., for displaying one or more indications of model learning.

Referring to FIG. 2, system 200 containing data set generator 272 (e.g., data set generator 172 of FIG. 1) creates data sets for a machine learning model (e.g., model 190 of FIG. 1). Data set generator 272 may create data sets using sensor data, e.g., historical sensor data 144 of FIG. 1. Data set generator 272 may create data sets using manufacturing parameters, e.g., historical parameters 152. Data set generator 272 may create data sets using metrology data, e.g., metrology data 160. In some embodiments, data set generator 272 may create data sets for a model using data output by another model, another function, another processing tool, or the like (e.g., predictive data 168, analytic data 169, simulated data 161, etc.). Models that receive different types of data than these as input or generate different types of data than these as output may receive data sets from data set generator 272 that were creating from corresponding data types. In some embodiments, data set generator 272 creates training input (e.g., data input 210) from sensor data associated with one or more processing procedures (e.g., associated with one or more produced substrates) and/or processing parameter data associated with one or more process recipes. Data set generator 272 also generates target output 220 for training a machine learning model. Target output may include metrology data, e.g., of one or more substrates processed in conditions indicated by the sensor data, processed according to the one or more process recipes, or the like. In some embodiments, metrology data 230 may include multiple measurements of a simulated wafer, e.g., each measurement corresponding to the predicted value of a feature of interest at a different spatial location of the simulated wafer. Training input data 210 and target output data 220 are supplied to a machine learning model. For the purposes of illustration of the operation of a data set generator for training a model, data set generator 272 is described as training a machine learning model that accepts input data indicative of processing conditions of a substrate and generates as output predicted metrology data of the substrate, but any other configuration of model (e.g., machine learning model) may benefit from aspects of the present disclosure.

It is within the scope of this disclosure for training input 210 and target output 220 to be represented in a variety of different ways. A two-dimensional map of substrate properties, a function recreating the map, or other data indicative of performance data of a substrate may be used as target output 220. Data sets may include processed data, smoothed data, cleaned data (e.g., outliers removed, etc.), combined data, data collected into data attributes (e.g., vectors, feature vectors, etc.), or the like

In some embodiments, data set generator 272 generates a data set (e.g., training set, validating set, testing set) that includes one or more data inputs 210 (e.g., training input, validating input, testing input) and may include one or more target outputs 220 that correspond to the data inputs 210. The data set may also include mapping data that maps the data inputs 210 to the target outputs 220. Data inputs 210 may also be referred to as “features,” “attributes,” or “information.” In some embodiments, data set generator 272 may provide the data set to the training engine 182, validating engine 184, or testing engine 186 of FIG. 1, where the data set is used to train, validate, or test model 190 of FIG. 1. Some embodiments of generating a training set may further be described with respect to FIG. 4A.

In some embodiments, data set generator 272 may generate a first data input corresponding to a first set of sensor data 244A and/or a first set of manufacturing parameter data 252A to train, validate, or test a first model and the data set generator 272 may generate a second data input corresponding to a second set of sensor data 244B and a second set of manufactured parameter data 252B to train, validate, or test a second model.

In some embodiments, data set generator 272 may perform operations on one or more of data input 210 and target output 220. Data set generator 272 may extract patterns from the data (slope, curvature, etc.), may combine data (average, feature production, etc.), or may separate data into groups (e.g., train a model on a subset of the predicted performance data) and use the groups to train separate models.

Data inputs 210 and target outputs 220 to train, validate, or test a model may include information for a particular substrate processing recipe (e.g., a particular substrate design). Data inputs 210 and target outputs 220 may include information for a particular substrate processing system (e.g., for a particular set of manufacturing equipment). Data inputs 210 and target outputs 220 may include information for a particular type of processing, target substrate design, target substrate property, or may be grouped together in another way.

In some embodiments, data set generator 272 may generate a set of target output 220, including metrology data 230. Target output 220 may be separated into sets corresponding to sets of input data. Different sets of target output 220 may be used in connection with the similarly defined sets of data input 210, including training different models, using different sets for training, validating, and testing, etc.

In some embodiments, a model may be trained without target output 220 (e.g., an unsupervised or semi-supervised model). A model trained that is not provided with target output may, for example, be trained to recognize significant (e.g., outside an error threshold) differences between predicted and measured performance data.

In some embodiments, the information used to train the model may be from specific types of manufacturing equipment (e.g., manufacturing equipment 124 of FIG. 1) of the manufacturing facility having specific characteristics and allow the trained machine learning model to determine outcomes for a specific group of manufacturing equipment 124 based on input of predicted performance data and measured performance data associated with one or more components sharing characteristics of the specific group. In some embodiments, the information used to train the model may be for components from two or more manufacturing facilities and may allow the model to determine outcomes for components based on input from one manufacturing facility.

In some embodiments, subsequent to generating a data set and training, validating, or testing a model using the data set, the model may be further trained, validated, or tested, or adjusted. For example, additional data may be provided to the model from substrates processed after the model was trained, validated, and tested as retraining data, revalidating data, retesting data, or the like.

Data set generator 272 may generate data sets to train, validate, and/or test a model. Training a model may include generating model mappings 273 that the model utilizes to connect input data to output data (e.g., to generate output from a provided set of inputs). In some embodiments, model mappings 273 may comprise weights and biases of a model, e.g., weights and biases connecting nodes of layers of a machine learning model.

In some embodiments, a data set generator performing similar functions to data set generator 272 may be utilized to train a physics-based model. A physics-based model may be configured to generate an output based on a physical understanding of a system, based on physical assumptions of the operation of a system, based on one or more numerical solutions to one or more physical equations (e.g., heat transfer equations, mass balance equations, fluid dynamics equations, etc.), or the like. A physics-based model may be trained in a similar manner to a machine learning model. The physics-based model may be provided with training input and target output, and may adjust one or more parameters, weights, biases, or the like, to bring model output into better alignment with the target output.

In some embodiments, a physics-based model may receive a set of inputs (e.g., indicative of processing conditions of a substrate). The physics-based model may generate an output based on the set of inputs (e.g., predicted metrology data of the substrate). The physics-based model may be provided with a target output (e.g., measured metrology data of the substrate). The physics-based model may adjust one or more parameters of the model to generate output (e.g., predicted metrology data) that is more similar to the target output than before the adjustment was made.

In some embodiments, data set generator 272 is to facilitate generation of a model for improving a manufacturing system. In some embodiments, a record of learning of the trained model is to be generated. For example, visual representation of lessons, associations, mappings, or the like, learned by the model (e.g., learned by providing the model with data sets created by data set generator 272) may be generated. Operations of data set generator 272 may facilitate generation of model mappings 273 (e.g., weights and biases of a machine learning model, values of adjustable parameters of a physics-based model, or the like). Visualization of learnings of the model may include visualizing model mappings 273, e.g., changes to outputs of a model as inputs are altered.

FIG. 3 is a block diagram illustrating system 300 for generating output data for analysis of learning, associations, and mappings of a model (e.g., generating analytic data 169 of FIG. 1), according to some embodiments. System 300 may be used to train a model (e.g., a machine learning model) and to generate data that may be utilized to describe the associations learned by the model. Some or all of the operations of system 300 may be used to generate output data of a machine learning model, e.g., predictive data 168 of FIG. 1. Some or all of the operations of system 300 may be used to generate output data of a physics-based model, e.g., predictive data 168 of FIG. 1.

Referring to FIG. 3, at block 310, the system 300 (e.g., components of predictive system 110 of FIG. 1) performs data partitioning (e.g., via data set generator 172 of server machine 170 of FIG. 1) of historical data 364 (e.g., historical sensor data, historical manufacturing parameter data, historical metrology data, etc.) to generate training set 302, validation set 304, and testing set 306. For example, the training set may be 60% of the historical data, the validation set may be 20% of the historical data, and the testing set may be 20% of the historical data.

At block 312, the system 300 performs model training (e.g., via training engine 182 of FIG. 1) using the training set 302. The system 300 may train one model or may train multiple models using multiple sets of attributes (e.g., feature vectors) of the training set 302 (e.g., a first set of attributes including a subset of historical data of the training set 302, a second set of attributes including a different subset of historical data of the training set 302, etc.). For example, system 300 may train a machine learning model to generate a first trained machine learning model using the first set of attributes in the training set and to generate a second trained machine learning model using the second set of attributes in the training set (e.g., different data than the data used to train the first machine learning model). In some embodiments, the first trained machine learning model and the second trained machine learning model may be combined to generate a third trained machine learning model (e.g., which may be a better predictor than the first or the second trained machine learning model on its own). In some embodiments, sets of attributes used in comparing models may overlap (e.g., one model may be trained with performance data indicative of film thickness, and another model with performance data indicative of both film thickness and film stress, different models may be trained with data from different locations of a substrate, models may be trained including input from a different set of sensors or manufacturing parameters, etc.). In some embodiments, hundreds of models may be generated including models with various permutations of attributes and combinations of models.

At block 314, the system 300 performs model validation (e.g., via validation engine 184 of FIG. 1) using the validation set 304. System 300 may validate each of the trained models using a corresponding set of attributes of the validation set 304. For instance, validation set 304 may use the same subset of historical data types (e.g., associated with the same on-wafer performance features, the same sensors, the same input parameters, etc.) used in training set 302, but for different input conditions. In some embodiments, the system 300 may validate hundreds of models (e.g., models with various permutations of attributes, combinations of models, etc.) generated at block 312. At block 314, the system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of attributes of the training set. Responsive to determining that one or more of the trained models has an accuracy that meets a threshold accuracy, flow continues to block 316. The system 300 may discard the trained machine learning models that have an accuracy that is below the threshold accuracy (e.g., based on the validation set).

At block 316, the system 300 may perform model selection (e.g., via selection engine 185 of FIG. 1) to determine which of the one or more trained models that meet the threshold accuracy has the highest accuracy (e.g., the selected model 308, based on the validating of block 314). If only a single model was trained, then the operations of block 316 may be skipped. Responsive to determining that two or more of the trained models that meet the threshold accuracy have the same accuracy, flow may return to block 312 where the system 300 performs model training using further refined training sets (e.g., corresponding to further refined sets of attributes) for determining a trained model that has the highest accuracy.

At block 318 system 300 performs model testing (e.g., via testing engine 186 of FIG. 1) using the testing set 306 to test the selected model 308. The system 300 may test, using the first set of attributes in the testing set, the first trained machine learning model to determine the first trained machine learning model meets a threshold accuracy (e.g., based on the first set of attributes of the testing set 306). Responsive to accuracy of the selected model 308 not meeting the threshold accuracy (e.g., the selected model 308 is overly fit to the training set 302 and/or validation set 304 and is not applicable to other data sets such as the testing set 306), flow continues to block 312 where the system 300 performs model training (e.g., retraining) using different training sets possibly corresponding to different sets of attributes or a reorganization of substrates (e.g., data sets) split into training, validation, and testing sets. Responsive to determining that the selected model 308 has an accuracy that meets a threshold accuracy based on the testing set 306, flow continues to block 320. In at least block 312, the model may learn patterns in the simulated sensor data to make predictions and in block 318, the system 300 may apply the model on the remaining data (e.g., testing set 306) to test the predictions.

At block 320, system 300 uses the trained model (e.g., selected model 308) to receive simulated data 354 (e.g., simulated data 161 of FIG. 1, simulated data of interest, a user-selected set of baseline inputs, inputs that span one or more dimensions of the input space or a portion thereof to map a spanned portion of the input space to a portion of the output space of the model, or the like) and determines (e.g., extracts), from the output of the trained model, analytic data 369 (e.g., analytic data 169 of FIG. 1) to perform an action (e.g., perform a corrective action in association with manufacturing equipment 124 of FIG. 1, provide an alert to client device 120 of FIG. 1, provide an alert to a user via presentation element 115 of FIG. 1, etc.).

In some embodiments, retraining of the machine learning model occurs by supplying additional data to further train the model. Current data 346 may be provided at block 312. Current data 346 may be different from the data originally used to train the model by incorporating combinations of input parameters not part of the original training, input parameters outside the parameter space spanned by the original training, or may be updated to reflect chamber specific knowledge (e.g., differences from an ideal chamber due to manufacturing tolerance ranges, aging components, drifting components, performed maintenance, etc.). Selected model 308 may be retrained based on this data.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed. In training a physics-based digital twin model, e.g., to take as input measurements of processing conditions and produce as output predicted performance data of a substrate, a subset of these operations may be performed.

FIGS. 4A-D are flow diagrams of methods 400A-D associated with describing and/or visualizing model learning, according to certain embodiments. Methods 400A-D may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-D may be performed, in part, by predictive system 110. Method 400A may be performed, in part, by predictive system 110 (e.g., server machine 170 and data set generator 172 of FIG. 1, data set generator 272 of FIG. 2). Predictive system 110 may use method 400A to generate a data set to at least one of train, validate, or test a model, in accordance with embodiments of the disclosure. The model may be a physics-based (e.g., digital twin) model (e.g., to generate predictive performance data of a substrate), a machine learning model (e.g., to generate predictive performance data of a wafer, to generate data indicative of a corrective action associated with a component of manufacturing equipment, etc.), a statistical model, or another model trained to receive input and generate output related to substrate manufacturing or processing. Methods 400B-D may be performed by predictive server 112 (e.g., predictive component 114, etc.). Methods 400B-D may be performed by other components of predictive system 110. Operations described as associated with methods 400B-D may be performed by server machine 180 (e.g., training engine 182). In some embodiments, a non-transitory storage medium stores instructions that when executed by a processing device (e.g., of predictive system 110, of server machine 180, of predictive server 112, etc.) cause the processing device to perform one or more of methods 400A-D.

For simplicity of explanation, methods 400A-D are depicted and described as a series of operations. However, operations in accordance with this disclosure can occur in various orders and/or concurrently and with other operations not presented and described herein. Furthermore, not all illustrated operations may be performed to implement methods 400A-D in accordance with the disclosed subject matter. In addition, those skilled in the art will understand and appreciate that methods 400A-D could alternatively be represented as a series of interrelated states via a state diagram or events.

FIG. 4A is a flow diagram of a method 400A for generating a data set for a model (e.g., a machine learning model) for generating output data (e.g., predictive data 168 of FIG. 1), according to some embodiments.

Referring to FIG. 4A, in some embodiments, at block 401 the processing logic implementing method 400A initializes a training set T to an empty set.

At block 402, processing logic generates first data input (e.g., first training input, first validating input) that may include sensor data, manufacturing parameter data, measured substrate performance data, substrate metrology data (e.g., film properties such as thickness, material composition, optical properties, roughness, and so on), etc. In some embodiments, the first data input may include a first set of attributes for types of data and a second data input may include a second set of attributes for types of data (e.g., as described with respect to FIG. 3).

At block 403, processing logic generates a first target output for one or more of the data inputs (e.g., first data input). In some embodiments, the first target output is performance data of substrates. In some embodiments, the first target output is data indicative of a corrective actions. In some embodiments, no target output is generated (e.g., for training an unsupervised machine learning model).

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments (e.g., those without target output data) these operations may not be performed.

At block 405, processing logic adds the mapping data generated at block 404 to data set T, in some embodiments.

At block 406, processing logic branches based on whether data set T is sufficient for at least one of training, validating, and/or testing model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other implementations, the sufficiency of data set T may be determined based on one or more other criteria (e.g., a measure of diversity of the data examples, accuracy, span of the input and/or output spaces, etc.) in addition to, or instead of, the number of inputs.

At block 407, processing logic provides data set T (e.g., to server machine 180 of FIG. 1) to train, validate, and/or test model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing.

Operations of block 407 may generate a trained model, e.g., may generate model mappings between inputs and outputs (e.g., values of weights and biases between nodes of layers of a machine learning model, values of adjustable parameters of a physics-based model, etc.). Model mappings may be described (e.g., indications of learning of the model may be visualized) via methods of this disclosure, e.g., any of methods 400A-D.

FIG. 4B is a flow diagram of a method 400B for generating a visual representation of learning (e.g., input to output mappings) of a model, according to some embodiments. In some embodiments, the model comprises a machine learning model. In some embodiments, the model comprises a physics-based model. In some embodiments, the model comprises a statistical model. In some embodiments, the model is configured to receive as input one or more indications of processing conditions for processing a substrate (e.g., sensor data, manufacturing parameters, etc.). In some embodiments, the model is configured to generate as output predicted features of a substrate processed according to conditions indicated by the input. In some embodiments, the model is configured to generate an indication of values of one or more predicted features of the substrate (e.g., substrate thickness at one or more locations, substrate resistivity at one or more locations, substrate sheet resistance, optical properties (e.g., extinction coefficient, refractive index), indications of substrate geometry (e.g., critical dimension, sidewall height, line width, depth, etc.), etc.). In some embodiments, one or more properties (e.g., statistical metrics) of the predicted features may be calculated. Properties may include average, median, standard deviation, uniformity, skew, kurtosis, quartile ranges, or any other statistical metric applicable to the predicted feature values. In some embodiments, analogous methods to method 400B may be utilized for generating a visual display of learning of models configured differently (e.g., configured to receive different data as input than the model described in method 400B and/or generate different data as output than the model described in method 400B).

In some embodiments, the model may be trained (e.g., prior to initiation of method 400B). Training the model may include providing training input to the model and target output to the model. Training the model may include processing logic receiving a plurality of sets of input values (e.g., values indicative of processing conditions for processing a plurality of substrates). The processing logic may also receive target output data for training the model (e.g., metrology measurements of substrates processed in processing conditions associated with the sets of input values). Training the model may include processing logic providing to the model the plurality of sets of input values as training input and the target output data as target output.

At block 410, processing logic receives a first value. The first value is associated with a first input parameter of a model (e.g., the model may accept the first value as a first input parameter). The first input parameter is associated with (e.g., represents a value corresponding to) a first processing condition of a substrate processing procedure. The first processing condition (and subsequent processing conditions of methods 400B-D) may be any processing condition of a substrate processing system that may have an effect on a product, e.g., temperature, gas flow, gas identity and/or mix (e.g., 20% reactive gas in a non-reactive carrier, 15% reactive gas in a non-reactive carrier, etc.), pressure, chucking power, radio frequency power, processing time, etc.

At block 412, processing logic receives a first plurality of values. The first plurality of values range from a lowest value of the first plurality of values to a highest value of the first plurality of values (e.g., the values span a range of values). In some embodiments, the values span a range determined by a user. In some embodiments, the values span a range determined by the trained model (e.g., defined relative to the model input space. In some embodiments, the values span a range that is a portion of a range related to the input space of the model (e.g., a user may select a range that is 10% of the full range, 20% of the full range, 30% of the full range, or any subset of the full range). Each of the first plurality of values is associated with a second input parameter of the model. The second input parameter of the model is associated with a second processing condition of the substrate processing procedure.

At block 414, processing logic provides to the model the first value and the first plurality of values. Processing logic may provide the first value and the first plurality of values as inputs to the model. The model may be configured to generate outputs based on the inputs. The inputs may include additional values (e.g., values associated with third, fourth, etc., input parameters). The model may generate output associated with each set of inputs (e.g., an input set including the first value and the first of the first plurality of values, an input set including the first value and the second of the first plurality of values, etc.) separately (e.g., sequentially) to generate output corresponding to each set of input values.

In some embodiments, processing logic may provide additional sets of inputs to the model. For example, the processing logic may receive a second value associated with the second input parameter of the model. The processing logic may further receive a second plurality of values, each of the second plurality of values associated with the first input parameter of the model. The processing logic may provide sets of inputs to the model, e.g., a first set including the second value and the first value of the second plurality of values, a second set including the second value and the second value of the second plurality of values, etc. Similar operations may be performed for additional pluralities of values associated with additional input parameters (e.g., associated with additional processing conditions). In some embodiments, a series of sets of values may be provided to the model, wherein each of the sets of values includes all values except one at central values, baseline values, values of interest, etc., and allows the other values to vary throughout a range. The series of sets of values may include a series of sets where each of the series includes a different varied input parameter. In this way, a collection of outputs, each tied to a baseline set of input values but with one parameter varied, may be obtained from the model. In some embodiments, more than one value may be varied in a set. For example, instead of a single baseline set of values, multiple baseline sets of values may be used, multiple values associated with input parameters may be varied within the same set (e.g., to show how varying two or more input parameters affects output, to demonstrate the learning of the model with respect to varying two or more input parameters, etc.), or the like.

In some embodiments, processing logic may receive a second value associated with the first input parameter of the model. For example, the GUI may include an option for a user to change the baseline value of the first input parameter. The system may perform analogous operations (e.g., providing the second value and the first plurality of values to the model, providing the second value and the second plurality of values to the model, etc.) responsive to receiving the user input, responsive to receiving instructions to perform operations based on the second value, etc. In some embodiments, a user may alter one or more baseline inputs, one or more ranges associated with pluralities of values, one or more features to be investigated, one or more properties to be displayed, etc., and the system may perform operations as described herein to demonstrate model learning, associations, mappings, or the like responsive to the user selection.

At block 416, processing logic receives a first plurality of outputs from the model. Each of the first plurality of outputs is associated with the first value (associated with the first input parameter of the model) and one value of the first plurality of values (associated with the second input parameter of the model). Each of the first plurality of outputs is associated with a first feature (e.g., a feature of a substrate the model is configured to predict) of one of a first plurality of simulated substrates.

In some embodiments, further results may be received from the model. For example, the model may provide a second plurality of outputs, a third plurality of outputs, and so on. The second plurality of outputs may be associated with a second value (e.g., a central or baseline value associated with the second input parameter) and a second plurality of values (e.g., a plurality of values associated with the first input parameter). In this way, the model may provide two or more series of output data, one associated with varying the first input parameter while holding the remainder of the parameter at a set of baseline values, the second associated with varying the second input parameter while holding the remainder of the parameters at the set of baseline values, and so on. In the example of two series of output data, visually, this may be represented as two arcs, curves, etc., each arc including a plurality of data points (e.g., each of the plurality of data points associated with one of a plurality of inputs). The curves may meet at a point (represented in output space) associated with the baseline set of input conditions (e.g., model output received when the baseline set of inputs are provided to the model as input).

In some embodiments, more input parameters may be varied, which may result in a larger number of curves. In some embodiments, multiple inputs may be varied to generate a curve (e.g., a curve may be generated where data points on the curve are associated with outputs of the model generated by adjusting two or more input parameters simultaneously). Varying multiple inputs may allow changes in one output feature, one property of the feature, or the like without affecting another. For example, altering two input parameters may have analogous effects (e.g., adjusting both input parameters to be higher values may shift a property of an output to a higher value) on one property, one feature, etc., but opposite effects (e.g., adjusting the first input parameter to be a higher value may shift a value of a property of an output in the opposite direction as adjusting the second parameter to be a higher value) on a second property, a second feature, or the like. A set of input parameters may be provided that holds all inputs at a baseline value except these two, with these two being varied simultaneously to, for example, maintain one output property or feature while adjusting the other property or feature.

In some embodiments, further results received from the model may include a third plurality of outputs, wherein each of the third plurality of outputs is associated with a second value associated with the first input parameter (e.g., a different set of baseline conditions) and a plurality of values associated with the second input parameter. In some embodiments, the plurality of values associated with the second input parameter may be the same as the values used in connection with the first value associated with the first input parameter. In some embodiments, the plurality of values may be different (e.g., one or more values may be different, there may be a different total number of values, etc.) from the plurality of values used in connection with the first value of the first input parameter. In this way a user may specify a different set of baseline input conditions. In some embodiments, more than one baseline condition (e.g., a baseline value associated with the second input parameter, a baseline value associated with a third input parameter, etc.) may be altered.

At block 418, the first plurality of outputs are prepared for presentation by processing logic. The first plurality of outputs (e.g., indicators of the outputs of the model) are to be presented via a presentation element of a graphical user interface (GUI). In one embodiment, the presentation element includes two axes (e.g., two orthogonal axes). In some embodiments, the presentation element may include three axes (e.g., three orthogonal axes). In some embodiments, the presentation element may include a scatter plot, e.g., each simulated substrate may be associated with a value corresponding to the first axis (e.g., a first property of a first feature) and a value corresponding to the second axis (e.g., a second property of a second feature), and a data point may be displayed at a location that indicates both of these values. The first axis of the two axes may correspond to a first property of the first feature (e.g. a first statistical metric of the feature the model is configured to predict). The second axis of the two axes may correspond to a second property of the first feature. Preparing the first plurality of outputs for presentation includes facilitating generation of a graphic for display in the presentation element. The graphic indicates a value of the first property of the first feature (e.g., by the location of a data point in reference to the first axis) and a value of the second property of the first feature (e.g., by the location of a data point in reference to the second axis) associated with each of the first plurality of outputs.

In some embodiments, the data points associated with each of the first plurality of outputs may generate a curve in the presentation element. In some embodiments, further output may also be plotted, e.g., generating additional curves. The further output may be represented as additional curves, e.g., meeting at a data point associated with the baseline set of inputs. In some embodiments, data associated with a second value of one or more input parameters (e.g., a second set of baseline conditions) may be presented. In some embodiments, responsive to a change of baseline input parameters, processing logic may generate a new graphic including new data points (e.g., one or more curves of data points) associated with the new baseline input condition. In some embodiments, the graphic may include data points (e.g., one or more curves of data points) associated with two or more sets of baseline conditions. In some embodiments, the graphic of the presentation element may include other features, such as an indication of the extent of an input space and/or output space of the model. In some embodiments, the graphic of the presentation element may include one or more visual indicators, e.g., for distinguishing outputs associated with each of a plurality of inputs. For example, a plurality of input values may range from a lowest value to a highest value. The output associated with the lowest input value may be distinguished from the output associated with the highest input value, e.g., via color, shape, pattern, labelling, or the like. Features of the presentation element and GUI are discussed in more detail in connection with FIGS. 5A-C.

FIG. 4C is a flow diagram of a method 400C for generating a visual representation of learning of multiple models, according to some embodiments. The models associated with method 400C may share one or more features with models described in connection with FIG. 4B. The operations associated with method 400C may share one or more features with operations of method 400B.

At block 420, processing logic receives a first value associated with a first input parameter of a first model. The first value is also associated with a first input parameter of a second model. The first input parameter is associated with a first processing condition of a substrate processing procedure (e.g., the first input parameter may be a measured and/or predicted value of a condition in the processing chamber, such as temperature, pressure, etc.). The first model may be configured to receive one or more inputs and generate as output one or more predictions of substrate performance (e.g., metrology of the substrate, material properties of the substrate, etc.). The first model may be configured to provide one or more indications associated with one feature of a simulated/predicted substrate (a feature may be thickness, another physical dimension, resistivity, or any other metric of interest). In some embodiments, the processing logic may further receive a second value, also associated with the first input parameter, a third value associated with a second input parameter, etc.

At block 422, processing logic receives a first plurality of values. The first plurality of values ranges from a lowest value of the first plurality of values to a highest value of the first plurality of values. Each of the first plurality of values is associated with a second input parameter of the first model. Each of the first plurality of values is also associated with a second input parameter of the second model. The second input parameter is associated with a second processing condition of the substrate processing procedure. In some embodiments, processing logic may receive further pluralities of values. Processing logic may receive a second plurality of values, associated with the first input parameter of the first and second models. Processing logic may receive a third plurality of values, associated with a third input parameter of the first and second models. Processing logic may receive a fourth plurality of values, which may be associated with the first input parameter but may include different values (e.g., a different range, different spacing, etc.) than the first plurality of values.

At block 424, processing logic provides to the first model the first value and the first plurality of values. Processing logic also provides to the second model the first value and the first plurality of values. In some embodiments, different and/or additional values are provided, e.g., the second value, the second plurality of values, the third plurality of values, etc.

At block 426, processing logic receives a first plurality of outputs from the first model. Each of the first plurality of outputs is associated with the first value and one value of the first plurality of values. Each of the first plurality of outputs is associated with a first feature (e.g., the feature of a simulated substrate the first model is configured to predict) of one of a first plurality of simulated substrates. In some embodiments, different and/or additional outputs may be received, e.g., outputs associated with the second value, the second plurality of values, etc.

At block 428, processing logic receives a second plurality of outputs from the second model. Each of the second plurality of outputs is associated with the first value and one value of the first plurality of values. Each of the second plurality of outputs is associated with a second feature (e.g., the feature of a simulated substrate that the second model is configured to predict) of one of the first plurality of simulated substrates. In some embodiments, different and/or additional outputs may be received, e.g., outputs associated with the second value, the second plurality of values, etc.

At block 429, processing logic prepares the first and second pluralities of outputs for presentation via a presentation element of a GUI. In some embodiments, additional outputs may further be prepared for presentation, e.g., outputs associated with different sets or pluralities of sets of inputs. The presentation element includes two axes. The first axis of the two axes corresponds to a first property of the first feature (e.g., the feature the first model is configured to predict one or more values of). The second axis of the two axes corresponds to a second property of the second feature (e.g., the feature the second model is configured to predict one or more values of). Preparing the first and second pluralities of outputs for presentation comprises facilitating generation of a graphic for display in the presentation element that indicates, for each simulated substrate of the first plurality of simulated substrates, a value of the first property of the first feature and a value of the second property of the second feature.

In some embodiments, the first and second properties (e.g., statistical metrics of one or more feature predictions) may be the same property (e.g., may both be an average value of feature predictions). In some embodiments, the first and second properties may be different properties. In some embodiments, the first model includes a machine learning model. In some embodiments, the second model includes a machine learning model. In some embodiments, one or more of the models are statistical models, physics-based models, or the like. In some embodiments, the generated graphic may share one or more features with that described in connection with FIG. 4B.

FIG. 4D is a flow diagram of a method 400D for generating a graphic demonstrating learning of a model, according to some embodiments. Method 400D may share one or more features with methods 400B and/or 400C.

At block 430, processing logic receives a first value associated with a first input parameter of a model. The first input parameter is associated with a processing recipe for processing a substrate. The first input parameter may be, for example, associated with a manufacturing parameter, a sensor reading, etc.

At block 432, processing logic receives a first plurality of values. The first plurality of values ranges from a lowest value of the first plurality of values to a highest value of the first plurality of values. Each of the first plurality of values is associated with a second input parameter of the model. The second input parameter is associated with the process recipe.

At block 434, processing logic provides, to the first model, the first value and the first plurality of values. The first model may be configured to generate one or more outputs predicting performance of a simulated substrate in response to receiving a set of input values.

At block 436, processing logic receives a first plurality of outputs from the model. Each of the first plurality of outputs is associated with the first value and one value of the first plurality of values (e.g., each output is an output generated by the model based on the first value being used as input for the first parameter and the one value of the first plurality of values being used as input for the second input parameter). Each of the first plurality of outputs is associated with a first feature of one of a first plurality of simulated substrates. In some embodiments, additional inputs may be provided to the model and additional outputs may be received from the model. The additional inputs may differ in one or more input parameters from the initial inputs. The additional inputs may provide different pluralities of inputs, different single values (e.g., different baseline conditions), or the like. Each output (e.g., each predicted feature, each set of predicted features, each property of a set of predicted features, or the like) may be associated with a set of inputs (e.g., one value for each input parameter). In some embodiments, additional sets of inputs may be provided to the model which may generate additional sets of outputs, e.g., outputs associated with a second plurality of simulated substrates.

At block 438, processing logic prepares the first plurality of outputs for presentation via a presentation element of a GUI. The presentation element comprises two axes (two independent axes, e.g., axes associated with values that are independent from each other). The first axis of the two independent axes corresponds to a first property of the first feature. Preparing the first plurality of outputs for presentation includes facilitating generation of a graphic for display in the presentation element. The graphic indicates a value of the first property of the first feature associated with the outputs of the first plurality of outputs.

FIG. 5A is an example presentation element 500A displaying indication of learning (e.g., input/output mappings, associations, etc.) of one or more models, according to some embodiments. Presentation element 500A includes first and second axes 502 and 504. The axes may be orthogonal, independent, or the like. First axis 502 may be associated with a first feature, a first property of a first feature, or the like. For example, presentation element 500A may be displaying data associated with one or more machine learning models to visualize learning (e.g., learned associations, learning input/output mappings, or the like) of the one or more models. First axis 502 may indicate a value of a first property of a first feature, e.g., a statistical metric associated with one or more predicted metrics of a simulated substrate. The second axis 504 may indicate a value of a second property of a second feature. In some embodiments, the first property is the same as the second property. In some embodiments, the first feature is the same as the second feature. In some embodiments, the first feature is associated with the output of a first model, and the second feature is associated with the output of a second model.

Presentation element 500A includes an indication of output space 506. Indication of output space 506 may include a number of data points as depicted in FIG. 5A. In some embodiments, data points of indication of output space 506 may be generated by providing a plurality of sets of input data (e.g., one set per output data point) to the one or more models associated with presentation element 500A. In some embodiments, the inputs associated with the output data points may span the input space of the model, may span a portion of the input space of the model, may be randomly selected from the input space of the model (e.g., enough points may be chosen to effectively/substantially span the input space of the model), or the like. In some embodiments, indication of output space 506 may be represented differently, e.g., by a region of presentation element 500A colored or shaded, by a portion of presentation element 500A encircled by a shape to indicate the output space of the one or more models, or the like.

Presentation element 500A may further include first curve 508 and second curve 510. First curve 508 may include a number of data points (represented in FIG. 5A as white-filled triangles). First curve 508 may include a visual distinction between outputs associated with a sets of inputs with one or more varied input values. For example, first curve 508 may be associated with a series of sets of input wherein each of the series maintains all inputs except a first input at a baseline value. The first input value may be varied from a minimum value to a maximum value. The shape of the data points representing output values may indicate a progression in the associated input values, e.g., the shape may lead from the output value associated with the set of inputs including the lowest value of the first input to the output value associated with the set of inputs including the highest value of the first input.

Second curve 510 may include a number of output data points (represented as black triangles). Second curve 510 may include output data points, each of which are associated with a set of input parameter values. Second curve 510 may include output data points associated with a series of sets of inputs such that each of the series is associated with altering the value of a second input parameter of the one or more models. First curve 508 and second curve 510 may cross at a region 512 (indicated by the dashed circle) associated with a baseline set of input parameter values.

In some embodiments, more than two input parameters may be varied, e.g., presentation element 500A may include more than two curves. Each curve may be associated with a different input parameter. In some embodiments, each curve may intersect at region 512. In some embodiments, different curves may be associated with different baseline sets of inputs, e.g., curves may cross in multiple regions of presentation element 500A. In some embodiments, only one curve may be presented (e.g., associated with varying one input parameter).

FIG. 5B is an example presentation element 500B depicting learning of one or more models, according to some embodiments. In some embodiments, a user may select a set of baseline input values. Presentation element 500B includes second curve 514 (e.g., including a series of data points each associated with a set of input parameter values, wherein each of the series includes all inputs set to a baseline value except the second input parameter). Presentation element 500B may be associated with the same model or models as presentation element 500A of FIG. 1. Presentation element 500B may be displayed responsive to processing logic receiving an adjustment to a set of baseline input values. Presentation element 500B may be displayed upon a user entering an adjusted set of baseline input values via a GUI.

First curve 508 and second curve 514 meet at region 516, e.g., region 516 may indicate one or more output values associated with the updated baseline set of inputs. In some embodiments, the same range of input values may be associated with a curve upon an adjustment to baseline conditions, e.g., curve 508 includes the same data points in presentation element 500A as presentation element 500B. In some embodiments, the range of input values, density of input values, values of the plurality of values, or the like may change when baseline conditions are altered. In some embodiments, responsive to a change in baseline conditions, a change to one or more pluralities of input values, or the like, one or more sets of input conditions may be provided to the one or models associated with presentation element 500B. Output from the one or more models may be displayed via presentation element 500B.

In some embodiments, one or more curves associated with a plurality of sets of input parameter values (e.g., varying one input parameter value from a minimum value to a maximum value) may be shaped differently depending upon the values of other input parameter values. For example, curve 510 may differ in shape from curve 514. Presentation elements 500A and 500B may be able to display such non-linearities in input/output mappings of the one or more models associated with the presentation elements succinctly by allowing a user to change the set of baseline values.

FIG. 5C is an example GUI 500C, according to some embodiments. GUI includes presentation element 520, e.g., including one or more features of presentation element 500B of FIG. 5B. GUI 500C further includes additional elements, e.g., elements presenting additional information to the user, elements for receiving from the user instructions, etc.

GUI 500C includes space settings element 522. Space settings element 522 may include one or more options related to the space displayed in presentation element 520, e.g., input space of the one or more models, output space of the one or more models, or the like. Space settings element 522 may include space editing element 524. Space editing element 524 may allow a user to adjust the input space of one or more parameters associated with one or more curves of presentation element 520. For example, space editing element 524 may open a window for editing one or more ranges of input values for generating one or more sets of data points (e.g., curves) of presentation element 520. For example, minimum values, maximum values, difference between adjacent values, number of values provided, or the like may be adjusted by space editing element 524.

Space settings element 522 may further include space restricting element 526. In some embodiments, an abbreviated region of model space (e.g., input space, output space, etc.) may be of particular interest. Space restricting element 526 may enable a user to restrict the space displayed by presentation element 520. For example, space restricting element 526 may allow a user to input a percent value. Presentation element 520 may present a portion of the max range of one or more varied input values (e.g., corresponding to the inputted percent value). In some embodiments, presentation element 520 may display the same number of data points (e.g., a user selected number) with a restricted space as an unrestricted space (e.g., an increased density of points if input space is restricted). In some embodiments, presentation element 520 may display a different number of data points in a restricted space than an unrestricted space. In some embodiments, responsive to a user selection via an element of space settings element 522, one or more series of sets of inputs may be provided to the one or more models.

GUI 500C may include presentation settings element 528. Presentation settings element 528 may be utilized to adjust various visual settings associated with presentation element 520. Settings such as data point shape, method of visual distinction between outputs associated with the lowest varied input value of a plurality of input values from the highest varied input value of a plurality of input values, data point and/or curve color, interval of data points presented (e.g., an option of presenting fewer data points than received from the one or more models), toggling the display of the feature representing the extent of the output space, or the like may be associated with presentation settings element 528.

GUI 500C may further include baseline adjustment element 530. Baseline adjustment element 530 may be utilized by a user to adjust the set of baseline values, e.g., adjust the point in input space around which input parameters are adjusted, adjust the point in output space at which two or more curves of output data points cross, etc. Baseline adjustment element 530 may enable altering the value of one or more baseline input parameters.

In some embodiments, baseline adjustment element 530 may include input selection element 532. Input selection element may enable a user choosing an input, the baseline input value of which is to be adjusted. Input selection element 532 may include a list, a drop-down list, a series of icons, a fillable field, open a window for input parameter selection, or the like. Baseline adjustment element 530 may further include value selecting element 534. Value selecting element may allow adjustment of the value of the input parameter indicated by input selection element 532. Value selecting element may include a fillable field, a slider, one or more buttons or icons, or the like.

In some embodiments, responsive to a user adjusting a baseline value associated with presentation element 520, a new graphic may be generated. The new graphic may include a new baseline value, e.g., two or more curves may extend from the new baseline value to depict changes in output based on varying input form the new baseline value. In some embodiments, responsive to the user adjusting the baseline value, new values are provided to the one or more machine learning models associated with generating data for presentation via presentation element 520.

GUI 500C may further include axes adjustment element 536. Axes adjustment element 536 may adjust the axes of presentation element 520. Axes adjustment element 536 may allow a user to adjust each axis separately, e.g., may allow adjustment of a first axis and adjustment of a second axis. In some embodiments, presentation element 520 may depict a three-dimensional plot (e.g., a three dimensional scatter plot of three dimensions of output space of one or more model). Axes adjustment element may allow a user to adjust a third axis.

Adjustments to an axis may include selecting a feature (e.g., a predicted feature and/or measurement of a simulated substrate) to be represented by the axis. In some embodiments, selection of a different feature may associated a different model (e.g., a machine learning model) with presentation element 520. Upon a user selecting one or more settings for an axis, one or more series of sets of input conditions may be provided to one or more models, and pluralities of outputs may be received from the one or more models for generation of the graphic presented in presentation element 520. In some embodiments, adjustment to an axis may include selecting a property (e.g., statistical metric) of a feature to be represented by the axis. Selection of one or more features and/or properties may include making a selection from a list, a set of icons or buttons, a fillable field, etc. In some embodiments, GUI 500C may display multiple graphics, e.g., multiple charts with varying properties corresponding to the first and second axes. The multiple charts may be utilized to simultaneously display additional learnings, input/output mappings, etc., of the models.

FIG. 5D is an example presentation element 500D depicting model learning associated with a number of varied input parameters, according to some embodiments. Presentation element 500D includes first axis 540. First axis 540 may correspond to a first property (e.g., a statistical metric) of a first feature (e.g., a model output) of a simulated substrate. Second axis 542 may correspond to a second property of a second feature. The second property may be the same as or different from the first property. The second feature may be the same as or different from the first feature.

Presentation element 500D may include indication of output space 544. Indication of output space 544 may be represented as a number of points (as shown), a shaded region, a bounded region, or the like. Indication of output space 544 may be generated by suppling a random sampling of input conditions to the one or more machine learning models associated with data of presentation element 500D. Indication of output space 544 may be generated by suppling a systematic sampling of input conditions to the one or more machine learning models associated with data of presentation element 500D.

Presentation element 500D includes curves 546. Each curve may be a representation of varying one input parameter from a maximum to minimum value, while holding all other input parameters at a set of baseline values. The output received when providing the baseline set of inputs to the one or models associated with the data of presentation element 500D may be represented by the location where the curves cross. Varying a first input while holding the other inputs at the set of baseline values may generate first curve 548, varying a second set of inputs may generate second curve 550, varying a third set of inputs while holding the other inputs at the set of baseline values may generate third curve 552, etc.

Presentation element 500D may display visually learning of one or models. The curves of presentation element 500D may display how output of a model changes as input is changed. For example, a user may target (e.g., in a new substrate manufacturing process, an updated substrate design, or the like) to reduce the second property of the second feature associated with second axis 542 (as indicated by the arrow). For example, the second property of the second feature may be an average thickness of a substrate, and a thinner substrate may be targeted. Curves 546 visually show which input parameters have an effect on the second feature in output space, and gives an indication of how strong the effect is, on the second property of the second feature in the vicinity of the set of baseline values (e.g., near, in input space, the baseline input).

A user may determine based on presentation element 500D that the input parameter associated with curve 552 does not have a strong effect (e.g., in comparison to other input parameters associated with other curves) on the second property of the second feature. For example, curve 552 may be associated with an input parameter such as gas pressure, and gas pressure may not have a strong effect on some output result such as substrate thickness. Strength of an effect may be estimated by a length of a curve, density of points along the curve, etc., depending for instance on the display settings of presentation element 500D.

A user may determine based on presentation element 500D that the input parameter associated with curve 550 does have a moderate effect (e.g., in comparison to other input parameters associated with other curves) on the second property of the second feature. For example, curve 550 may be associated with an input parameter such as temperature, and temperature may have an effect on an output result such as average substrate thickness (e.g., as learned by one or more machine learning models). Presentation element 500D provides further insight associated with first axis 540, indicating that altering the input value associate with curve 550 will not have a strong effect on a second output property. For example, the second property of the second feature may be an average resistivity of the substrate. Presentation element 500D may make it visually clear that altering an input value associated with curve 550 (e.g., temperature) will have an effect on a second property of a second feature (e.g., thickness of the substrate, indicated by second axis 542) but will not have a strong effect on the first property of a first feature (e.g., resistivity).

A user may determine based on presentation element 500D that the input parameter associated with curve 548 has a strong effect (e.g., in comparison to other input parameters associated with other curve) on the second property of the second feature. For example, curve 548 may be associated with an input parameter such as process time, and process time may have an effect on an output result such as average substrate thickness.

Input associated with curve 548 also has a strong effect on the first property of the first feature, e.g., average resistivity. A user can easily see the effect that altering the input parameter associated with curve 548 will have on both the property associated with first axis 540 and the property associated with second axis 542. Presentation element 500D may show non-linear learning of one or more models, e.g., as the input parameter associated with curve 548 is changed, the second property decreases for a time, and then increases. These nonlinearities are not captured by traditional model learning presentations (e.g., bar graphs), which may only display learning in the immediate vicinity of a baseline set of conditions. Utilizing a GUI associated with presentation element 500D, the baseline set of conditions may be altered, and the pattern of curves 546 associated with a different set of baseline conditions (e.g., baseline conditions around a different portion of one of the curves displayed by presentation element 500D) may be displayed. A user may use displayed learning of one or more models to, for example, build intuition about how substrate processing conditions effect substrate properties. Displayed learning may be used to visually confirm a corrective action (e.g., confirm the effects of updating a process recipe). Displayed learning may be used to communicate to a user that the model has generated logical associations between input and output (e.g., a user may be more likely to trust a model when it can be displayed that the model matches their intuition, that a model matches their experience, that a model includes associations that are not immediately suspicious, indicated for example by discontinuities in one or more curves, etc.). Displayed learning may be used to indicate reliability of a model, e.g., swiftly oscillating or discontinuous curves may indicate an unreliability of a model, a sampling bias or incompleteness of a training set, or the like.

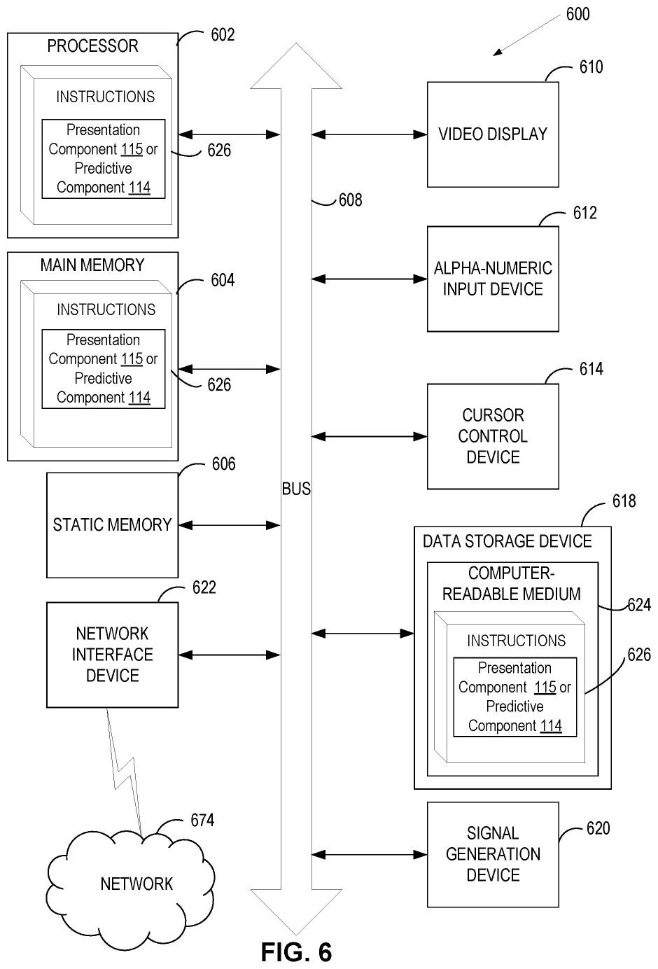

FIG. 6 is a block diagram illustrating a computer system 600, according to certain embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some implementations, data storage device 618 may include a non-transitory computer-readable storage medium 624 (e.g., non-transitory machine-readable storage medium) on which may store instructions 626 encoding any one or more of the methods or functions described herein, including instructions encoding components of FIG. 1 (e.g., predictive component 114, presentation component 115, model 190, etc.) and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “generating,” “preparing,” “training,” “facilitating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A non-transitory machine-readable storage medium storing instructions which, when executed, cause a processing device to perform operations comprising:
receiving, by the processing device, a first value associated with a first input parameter of a model, wherein the first input parameter is associated with a first processing condition of a semiconductor wafer processing procedure;
receiving, by the processing device, a first plurality of values, wherein the first plurality of values ranges from a lowest value of the first plurality of values to a highest value of the first plurality of values, and wherein each of the first plurality of values is associated with a second input parameter of the model, wherein the second input parameter is associated with a second processing condition of the semiconductor wafer processing procedure;
providing, by the processing device, to the model the first value and the first plurality of values;
receiving, by the processing device, a first plurality of outputs from the model, wherein each of the first plurality of outputs is associated with the first value and one value of the first plurality of values, and wherein each of the first plurality of outputs is associated with a first feature of one of a first plurality of simulated semiconductor wafers; and
preparing, by the processing device, the first plurality of outputs for presentation via a presentation element of a graphical user interface (GUI), wherein the presentation element comprises two axes, a first axis of the two axes corresponding to a first property of the first feature, and a second axis of the two axes corresponding to a second property of the first feature, and wherein preparing the first plurality of outputs for presentation comprises facilitating generation of a graphic for display in the presentation element that indicates a value of the first property of the first feature and a value of the second property of the first feature associated with each of the first plurality of outputs.

2. The non-transitory machine-readable storage medium of claim 1, wherein the model comprises a machine learning model.

3. The non-transitory machine-readable storage medium of claim 2, the operations further comprising:
receiving a plurality of sets of input values;
receiving a plurality of metrology measurements, wherein each of the plurality of metrology measurements is associated with one of the plurality of sets of input values; and
training the model to generate simulated metrology measurements of a simulated semiconductor wafer using the plurality of sets of input values and the plurality of metrology measurements, wherein training the model comprises providing the plurality of sets of input values to the model as training input, and providing the plurality of metrology measurements to the model as target output.

4. The non-transitory machine-readable storage medium of claim 1, wherein the first feature comprises at least one of:
semiconductor wafer thickness;
semiconductor wafer resistivity;
semiconductor wafer sheet resistance;
semiconductor wafer refractive index;
semiconductor wafer extinction coefficient; or
an indication of semiconductor wafer geometry.

5. The non-transitory machine-readable storage medium of claim 1, wherein the first property of the first feature comprises a statistical metric associated with simulated metrology measurements at a plurality of locations of the simulated semiconductor wafer, wherein the statistical metric comprises at least one of:
an average of values of the first feature;
a median of values of the first feature;
a standard deviation of values of the first feature; or
a uniformity of values of the first feature.

6. The non-transitory machine-readable storage medium of claim 1, the operations further comprising:
receiving, by the processing device, a second value associated with the second input parameter of the model;
receiving, by the processing device, a second plurality of values, wherein the second plurality of values ranges from a lowest value of the second plurality of values to a highest value of the second plurality of values, and wherein each of the second plurality of values is associated with the first input parameter of the model;
providing, by the processing device, to the model the second value and the second plurality of values;
receiving, by the processing device, a second plurality of outputs from the model, wherein each of the second plurality of outputs is associated with the second value and one value of the second plurality of values, and wherein each of the second plurality of outputs is associated with the first feature of one of a second plurality of simulated semiconductor wafers; and
preparing, by the processing device, the second plurality of outputs for presentation via the presentation element of the GUI, wherein preparing the second plurality of outputs for presentation comprises facilitating generation of a graphic for display in the presentation element that indicates the first property of the first feature and the second property of the first feature associated with each of the second plurality of outputs.

7. The non-transitory machine-readable storage medium of claim 1, wherein preparing, by the processing device, the first plurality of outputs for presentation further comprises facilitating generation of a graphic for display in the presentation element that visually distinguishes an output of the first plurality of outputs associated with the highest value of the first plurality of values from an output of the first plurality of outputs associated with the lowest value of the first plurality of values.

8. The non-transitory machine-readable storage medium of claim 1, the operations further comprising:
receiving, by the processing device, a second value associated with the first input parameter of the model;
providing, by the processing device, to the model the second value and the first plurality of values;
receiving, by the processing device, a second plurality of outputs from the model, wherein each of the second plurality of outputs is associated with the second value and one of the first plurality of values, and wherein each of the second plurality of outputs is associated with a first feature of one of a second plurality of simulated semiconductor wafers; and
preparing, by the processing device, the second plurality of outputs for presentation via the presentation element, wherein preparing the second plurality of outputs for presentation comprises facilitating generation of a graphic for display in the presentation element that indicates a value of the first property of the first feature and a value of the second property of the first feature associated with each of the second plurality of outputs.

9. A non-transitory machine-readable storage medium storing instructions which, when executed, cause a processing device to perform operations comprising:
receiving, by the processing device, a first plurality of outputs from a first model, wherein each of the first plurality of outputs is associated with a first input value and one value of a first plurality of input values, and wherein each of the first plurality of outputs is associated with a first feature of one of a first plurality of simulated substrates;
receiving, by the processing device, a second plurality of outputs from a second model, wherein each of the second plurality of outputs is associated with the first value and one value of the first plurality of values, and wherein each of the second plurality of outputs is associated with a second feature of one of the first plurality of simulated substrates; and
preparing, by the processing device, the first and second pluralities of outputs for presentation via a presentation element of a graphical user interface (GUI), wherein the presentation element comprises two axes, a first axis of the two axes corresponding to a first property of the first feature, and a second axis of the two axes corresponding to a second property of the second feature, and wherein preparing the first and second pluralities of outputs for presentation comprises facilitating generation of a graphic for display in the presentation element that indicates, for each simulated substrate of the first plurality of simulated substrates, a value of the first property of the first feature and a value of the second property of the second feature.

10. The non-transitory machine-readable storage medium of claim 9, wherein the first model comprises a first machine learning model, and wherein the second model comprises a second machine learning model.

11. The non-transitory machine-readable storage medium of claim 10, the operations further comprising:
receiving a first plurality of sets of input values;
receiving a second plurality of sets of input values;
receiving a first plurality of metrology measurements, wherein each of the first plurality of metrology measurements is associated with one of the first plurality of sets of input values;
receiving a second plurality of metrology measurements, wherein each of the second plurality of metrology measurements is associated with one of the second plurality of sets of input values;
training the first model to generate first simulated metrology measurements of a simulated substrate using the first plurality of sets of input values and the first plurality of metrology measurements, wherein training the first model comprises providing the first plurality of sets of input values to the first model as training input, and providing the first plurality of metrology measurements to the first model as target output; and
training the second model to generate second simulated metrology measurements of the simulated substrate using the second plurality of sets of input values and the second plurality of metrology measurements, wherein training the second model comprises providing the second plurality of sets of input values to the second model as training input, and providing the second plurality of metrology measurements to the second model as target output.

12. The non-transitory machine-readable storage medium of claim 9, wherein the first feature comprises at least one of:
substrate thickness;
substrate resistivity;
substrate sheet resistance;
substrate refractive index;
substrate extinction coefficient; or
an indication of substrate geometry.

13. The non-transitory machine-readable storage medium of claim 9, wherein the first property of the first feature comprises a statistical metric associated with simulated metrology measurements at a plurality of locations of one of the first plurality of simulated substrates, wherein the statistical metric comprises at least one of:
an average of values of the first feature;
a median of values of the first feature;
a standard deviation of values of the first feature; or
a uniformity of values of the first feature.

14. The non-transitory machine-readable storage medium of claim 9, wherein preparing, by the processing device, the first plurality of outputs and the second plurality of outputs for presentation further comprises facilitating generation of a graphic for display in the presentation element that visually distinguishes a presented data point associated with a first simulated substrate of the first plurality of simulated substrates that is associated with the highest value of the first plurality of values from a presented data point associated with a second simulated substrate of the first plurality of simulated substrates that is associated with the lowest value of the first plurality of values.

15. The non-transitory machine-readable storage medium of claim 9, further comprising:
receiving, by the processing device, the first input value, the first input value being associated with a first input parameter of:
the first model; and
the second model, wherein the first input parameter is associated with a first processing condition of a substrate processing procedure; and
receiving, by the processing device, the first plurality of input values, wherein the first plurality of input values ranges from a lowest value of the first plurality of values to a highest value of the first plurality of values, and wherein each of the first plurality of values is associated with a second input parameter of:
the first model; and
the second model, wherein the second input parameter is associated with a second processing condition of the substrate processing procedure.

16. The non-transitory machine-readable storage medium of claim 15, the operations further comprising:
receiving, by the processing device, a second value associated with the second input parameter of the first and second models;
receiving, by the processing device, a second plurality of values, wherein the second plurality of values ranges from a lowest value of the second plurality of values to a highest value of the second plurality of values, and wherein each of the second plurality of values is associated with the first input parameter of the first and second models;
providing, by the processing device, to the first model the second value and the second plurality of values;
providing, by the processing device, to the second model the second value and the second plurality of values;
receiving, by the processing device, a third plurality of outputs from the first model, wherein each of the third plurality of outputs is associated with the second value and one value of the second plurality of values, and wherein each of the third plurality of outputs is associated with the first feature of one of a second plurality of simulated substrates;
receiving, by the processing device, a fourth plurality of outputs from the second model, wherein each of the fourth plurality of outputs is associated with the second value and one value of the second plurality of values, and wherein each of the fourth plurality of outputs is associated with the second feature of one of the second plurality of simulated substrates;
preparing, by the processing device, the third plurality of outputs and the fourth plurality of outputs for presentation via the presentation element of the GUI, wherein preparing the third and fourth pluralities of outputs for presentation comprises facilitating generation of a graphic for display in the presentation element that indicates, for each simulated substrate of the second plurality of simulated substrates, a value of the first property of the first feature and a value of the second property of the second feature.

17. The non-transitory machine-readable storage medium of claim 15, the operations further comprising:
receiving, by the processing device, a second value associated with the first input parameter of the first and second models;
providing, by the processing device, to the first and second models the second value and the first plurality of values;
receiving, by the processing device, a third plurality of outputs from the first model and a fourth plurality of outputs from the second model, wherein each of the third plurality of outputs and each of the fourth plurality of outputs is associated with the second value and one of the first plurality of values, and wherein each of the third plurality of outputs is associated with the first feature of one of a second plurality of simulated substrates, and wherein each of the fourth plurality of outputs is associated with the second feature of one of the second plurality of simulated substrates; and
preparing, by the processing device, the third and fourth pluralities of outputs for presentation via the presentation element, wherein preparing the third and fourth pluralities of outputs for presentation comprises facilitating generation of a graphic for display in the presentation element that indicates, for each of the second plurality of simulated substrates, an associated value of the first property of the first feature and an associated value of the second property of the second feature.

18. A method, comprising:
receiving, by one or more processors, a first value associated with a first input parameter of a first model, wherein the first input parameter is associated with a process recipe for processing a substrate;
receiving, by the one or more processors, a first plurality of values, wherein the first plurality of values range from a lowest value of the first plurality of values to a highest value of the first plurality of values, and wherein each of the first plurality of values is associated with a second input parameter of the first model, wherein the second input parameter is associated with the process recipe;
providing, by the one or more processors, to the first model the first value and the first plurality of values;
receiving, by the one or more processors, a first plurality of outputs from the first model, wherein each of the first plurality of outputs is associated with the first value and one of the first plurality of values, and wherein each of the first plurality of outputs is associated with a first feature of a simulated substrate; and
preparing, by the one or more processors, the first plurality of outputs for presentation via a presentation element of a graphical user interface (GUI), wherein the presentation element comprises two independent axes, a first axis of the two independent axes corresponding to a first property of the first feature, and wherein preparing the first plurality of outputs for presentation comprises facilitating generation of a graphic in the presentation element that visually displays a relationship of the outputs of the first plurality of outputs to the first property of the first feature.

19. The method of claim 18, further comprising:
providing, by the one or more processors, to a second model the first value and the first plurality of values;
receiving, by the one or more processors, a second plurality of outputs from the second model, wherein each of the second plurality of outputs is associated with a second feature; and
preparing, by the one or more processors, the second plurality of outputs for presentation via the presentation element of the GUI, wherein the second of the two independent axes corresponds to a second property of the second feature, and wherein preparing the first and second pluralities of outputs for presentation comprises facilitating generation of a graphic in the presentation element that visually displays a relationship of the first plurality of outputs and the second plurality of outputs to the first property of the first feature and the second property of the second feature.

20. The method of claim 18, further comprising:
receiving, by the one or more processors, a second value associated with the second input parameter of the first model;
receiving, by the one or more processors, a second plurality of values, wherein the second plurality of values range from a lowest value of the second plurality of values to a highest value of the second plurality of values, and wherein each of the second plurality of values is associated with the first input parameter of the first model;
providing, by the one or more processors, to the first model the second value and the second plurality of values;
receiving, by the one or more processors, a second plurality of outputs from the first model, wherein each of the second plurality of outputs is associated with the second value and one of the second plurality of values, and wherein each of the second plurality of outputs is associated with the first feature; and
preparing, by the one or more processors, the second plurality of outputs for presentation via the presentation element of the GUI, wherein preparing the second plurality of outputs for presentation comprises facilitating generation of a graphic in the presentation element that visually displays a relationship of the first plurality of outputs and the second plurality of outputs to the first property of the first feature.
